(19) United States
(12) Patent Application Publication
(10) Pub. No.: US 2023/0065336 A1
(43) Pub. Date: Mar. 2, 2023

(54) DISPLAY DEVICE

(71) Applicant: Samsung Display Co., LTD., Yongin-si (KR)

(72) Inventors: Joo Woan CHO, Seongnam-si (KR); Dae Ho SONG, Hwaseong-si (KR); Byung Choon YANG, Seoul (KR); Tae Hee LEE, Hwaseong-si (KR); Byeong Hwa CHOI, Seoul (KR); Hae Yun CHOI, Hwaseong-si (KR)

(21) Appl. No.: 17/821,129

(22) Filed: Aug. 19, 2022

(30) Foreign Application Priority Data
Aug. 24, 2021 (KR) 10-2021-0111700

(51) Int. Cl. H01L 33/62; H01L 33/38; H01L 25/075; H01L 33/64; H01L 33/50

(52) U.S. Cl. CPC H01L 33/62; H01L 33/382; H01L 25/0753; H01L 33/642; H01L 33/505

(57) ABSTRACT

A display device is provided. The display device incudes a circuit substrate including pixel circuit units, and pads electrically connected to the pixel circuit units, a display substrate above the circuit substrate, including light-emitting elements electrically connected to the pixel circuit units, and defining via holes in a peripheral area around a cell part where the light-emitting elements are located, a circuit board above the display substrate, and including circuit board pads electrically connected to the pads, a heat dissipation substrate below the circuit substrate, and pad connecting electrodes in the via holes, and connected to the pads of the circuit substrate and to the circuit board pads of the circuit board.

### CROSS-REFERENCE TO RELATED APPLICATION

This application claims priority to, and the benefit of, Korean Patent Application No. 10-2021-0111700 filed on Aug. 24, 2021 in the Korean Intellectual Property Office, the contents of which in its entirety are herein incorporated by reference.

### BACKGROUND

### 1. Field

The disclosure relates to a display device.

### 2. Description of the Related Art

As the information society develops, demands for display devices for displaying images are increasing in various forms. The display devices may be flat panel displays, such as liquid crystal displays, field emission displays, and light emitting displays. The light emitting displays may include an organic light emitting display including an organic light emitting diode element as a light emitting element, or an inorganic light emitting display including an inorganic semiconductor element as a light emitting element.

Recently, a head-mounted display including a light emitting display has been developed. The head-mounted display is a virtual reality (VR) or augmented reality (AR) glasses-type monitor device that is worn by a user in the form of glasses or a helmet, and forms a focus at a relatively short distance in front of the eyes.

### SUMMARY

Embodiments of the disclosure provide an ultrahigh-resolution display device including inorganic light-emitting elements and having a relatively large number of emission areas per unit area.

Embodiments of the disclosure also provide a display device having a simplified connection structure between a circuit board and a circuit substrate.

However, embodiments of the disclosure are not restricted to those set forth herein. The above and other embodiments of the disclosure will become more apparent to one of ordinary skill in the art to which the disclosure pertains by referencing the detailed description of the disclosure given below.

According to some embodiments of the disclosure, a display device includes a circuit substrate including pixel circuit units, and pads electrically connected to the pixel circuit units, a display substrate above the circuit substrate, including light-emitting elements electrically connected to the pixel circuit units, and defining via holes in a peripheral area around a cell part where the light-emitting elements are located, a circuit board above the display substrate, and including circuit board pads electrically connected to the pads, a heat dissipation substrate below the circuit substrate, and pad connecting electrodes in the via holes, and connected to the pads of the circuit substrate and to the circuit board pads of the circuit board.

The pad connecting electrodes may include first electrode parts connected to the pads, second electrode parts connected to the circuit board pads, and connecting parts in the via holes and connected to the first electrode parts and to the second electrode parts.

The via holes and the circuit board pads may correspond to the pads, wherein a number of via holes and a number of the circuit board pads are the same as a number of pads.

The light-emitting elements may include a first semiconductor layer, an active layer on the first semiconductor layer, and a second semiconductor layer on the active layer, wherein the first semiconductor layer, the active layer, and the second semiconductor layer are further in the peripheral area around the cell part, and wherein the display substrate further includes a third semiconductor layer in both the cell part, and in the peripheral area around the cell part.

The pads and the circuit board pads may overlap with a part of the first semiconductor layer, the active layer, or the second semiconductor layer in the peripheral area around the cell part.

The via holes may penetrate the first semiconductor layer, the active layer, the second semiconductor layer, and the third semiconductor layer in the peripheral area around the cell part, wherein the second electrode parts are on the third semiconductor layer.

Parts of the second semiconductor layer and the third semiconductor layer may be omitted from the peripheral area around the cell part, wherein the via holes penetrate the active layer and the first semiconductor layer in the peripheral area around the cell part where the second semiconductor layer and the third semiconductor layer are omitted.

A top surface of the display substrate may be lower in regions where the via holes are located than in other regions of the peripheral area around the cell part.

The display substrate may further include color control structures on the third semiconductor layer in the cell part, color filters on the color control structures, and a second substrate on the color filters.

The display substrate may further include a third substrate on the third semiconductor layer, wherein the via holes penetrate the third substrate, and wherein the second electrode parts are on the third substrate.

Parts of the second semiconductor layer in the light-emitting elements may be connected to part of the second semiconductor layer in the peripheral area around the cell part.

The circuit board may define a first opening corresponding to the cell part of the display substrate, wherein the circuit board does not overlap with the cell part of the display substrate, and is in the peripheral area around the cell part.

A top surface of the cell part of the display substrate may protrude from a top surface of the circuit board.

The display device may further include a light-blocking layer on the circuit board, and defining a second opening corresponding to the cell part of the display substrate.

According to some embodiments of the disclosure, a display device includes a circuit substrate including a display area, and pad areas where pads are located, a display substrate above the circuit substrate, including a cell part where light-emitting elements correspond to the display area, defining via holes corresponding to the pads in a peripheral area around the cell part, and further including pad connecting electrodes in the via holes, a circuit board above the display substrate, defining a first opening corresponding to the cell part of the display substrate, and including circuit board pads corresponding to the pads, a light-blocking layer above the circuit board, and defining a second opening corresponding to the cell part of the display substrate, and a heat dissipation substrate below the circuit substrate, wherein the pad connecting electrodes include first electrode parts connected to the pads, second electrode parts connected to the circuit board pads, and connecting parts connected to the first electrode parts and the second electrode parts and in the via holes.

The light-emitting elements may include a first semiconductor layer, an active layer on the first semiconductor layer, and a second semiconductor layer on the active layer in the peripheral area around the cell part, wherein the display substrate further includes a third semiconductor layer in both the cell part, and the peripheral area around the cell part.

The via holes may penetrate the first semiconductor layer, the active layer, the second semiconductor layer, and the third semiconductor layer in the peripheral area around the cell part, wherein the second electrode parts are on the third semiconductor layer.

The display substrate may further include color control structures on the third semiconductor layer in the cell part, color filters on the color control structures, and a second substrate on the color filters, wherein a top surface of the cell part of the display substrate is higher than a top surface of the circuit board.

The circuit board pads may be at a bottom surface of the circuit board.

A number of the via holes and a number of the circuit board pads may be the same as a number of the pads.

According to the aforementioned and other embodiments of the disclosure, a circuit board and a circuit substrate, which are located above and below a display substrate including light-emitting elements, can be electrically connected via pad connecting electrodes, which are located on the display substrate. As a display device can be fabricated by sequentially stacking multiple substrates or multiple layers, the structure and the fabrication of the display device can be simplified, and the display device can have a suitable structure for effectively releasing heat.

Other aspects and embodiments may be apparent from the following detailed description, the drawings, and the claims.

### BRIEF DESCRIPTION OF THE DRAWINGS

The above and other embodiments and features of the disclosure will become more apparent by describing in detail embodiments thereof with reference to the attached drawings, in which:

FIG. 1 is a perspective view of a display device according to some embodiments of the disclosure;

FIG. 2 is an exploded perspective view of the display device of FIG. 1;

FIG. 3 is a cross-sectional view taken along the line I-I′ of FIG. 1;

FIG. 4 is a cross-sectional view taken along the line II-II′ of FIG. 1;

FIG. 5 is a plan view illustrating a circuit substrate and a display substrate of the display device of FIG. 1;

FIG. 6 is a plan view illustrating part A of FIG. 5;

FIG. 7 is a plan view illustrating part B of FIG. 6;

FIG. 8 is a circuit diagram illustrating a pixel circuit unit and a light-emitting element according to some embodiments of the disclosure;

FIGS. 9 and 10 are circuit diagrams illustrating pixel circuit units and light-emitting elements according to other embodiments of the disclosure;

FIG. 11 is a cross-sectional view taken along the line L1-L1′ of FIG. 6;

FIG. 12 is a cross-sectional view of a light-emitting element according to some embodiments of the disclosure;

FIG. 13 is a plan view illustrating the layout of light-emitting elements of the display device of FIG. 1;

FIG. 14 is a plan view illustrating the layout of color filters of the display device of FIG. 1;

FIG. 15 is a cross-sectional view illustrating part of a display device according to other embodiments of the disclosure;

FIG. 16 is a cross-sectional view taken across the display device of FIG. 15 in a second direction;

FIGS. 17 and 18 are cross-sectional views illustrating parts of display devices according to other embodiments of the disclosure;

FIG. 19 is a cross-sectional view illustrating part of a display device according to other embodiments of the disclosure;

FIG. 20 is a perspective view of a display device according to other embodiments of the disclosure;

FIG. 21 is an exploded perspective view of the display device of FIG. 20;

FIG. 22 is a cross-sectional view taken along the line III-III′ of FIG. 20;

FIG. 23 is a perspective view of a display device according to other embodiments of the disclosure;

FIG. 24 is an exploded perspective view of the display device of FIG. 23;

FIG. 25 is a cross-sectional view taken along the line IV-IV′ of FIG. 23;

FIG. 26 is a cross-sectional view taken along the line V-V′ of FIG. 23;

FIG. 27 is a perspective view illustrating the layers in part of the display device of FIG. 23;

FIG. 28 is a perspective view illustrating part of the display device of FIG. 23;

FIGS. 29 through 31 are perspective views illustrating devices each including one or more display devices according to some embodiments of the disclosure; and

FIGS. 32 and 33 are perspective views of transparent display devices including a display device according to some embodiments of the disclosure.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers also may be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. also may be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

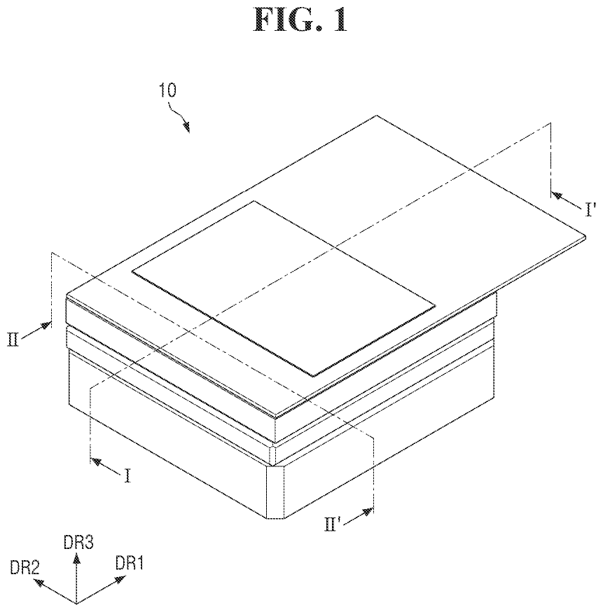

FIG. 1 is a perspective view of a display device according to some embodiments of the disclosure.

Referring to FIG. 1, a display device 10 displays a moving or still image. The display device 10 may refer to nearly all types of electronic devices that provide a display screen. Examples of the display device 10 may include a television (TV), a notebook computer, a monitor, a billboard, an Internet-of-Things (IoT) device, a mobile phone, a smartphone, a tablet personal computer (PC), an electronic watch, a smartwatch, a watchphone, a head-mounted display (HMD), a mobile communication terminal, an electronic notepad, an electronic book (e-book), a portable multimedia player (PMP), a navigation device, a gaming console, a digital camera, a camcorder, and the like.

The display device 10 includes a display panel that provides a display screen. Examples of the display panel of the display device 10 include an inorganic light-emitting diode (LED) display panel, an organic light-emitting diode (OLED) display panel, a quantum-dot light-emitting diode (QLED) display panel, a plasma display panel (PDP), a field-emission display (FED) panel, and the like. The display panel of the display device 10 will hereinafter be described as being, for example, a display panel having inorganic LEDs located on a semiconductor circuit substrate, but the disclosure is not limited thereto. That is, various other display panels are also applicable to the display panel of the display device 10.

The shape of the display device 10 may vary. For example, the display device 10 may have a rectangular shape extending longer in a horizontal direction than in a vertical direction, a rectangular shape extending longer in the vertical direction than in the horizontal direction, a square shape, a tetragonal shape with rounded corners, a non-tetragonal polygonal shape, or a circular shape. The shape of the display area DPA of the display device 10 may be similar to the shape of the display device 10. FIG. 1 illustrates that the display device 10 has a rectangular shape extending longer in a second direction DR2 than in a first direction DR1.

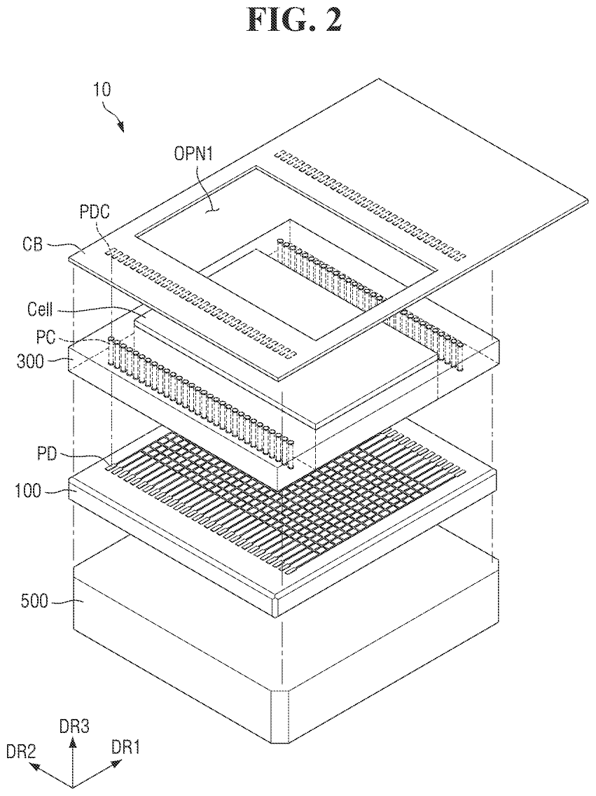

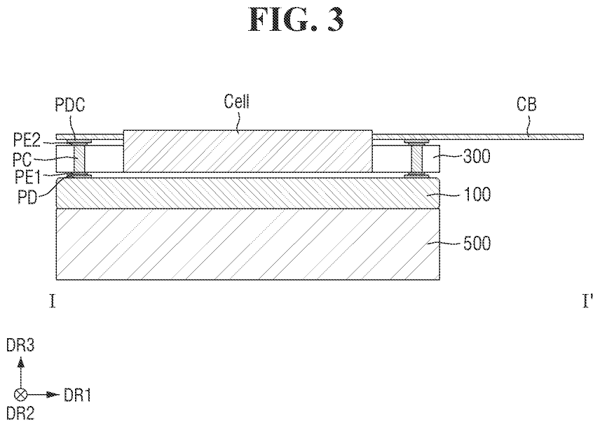

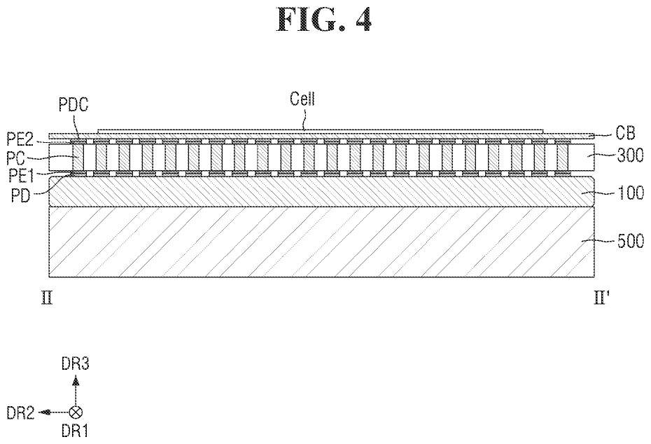

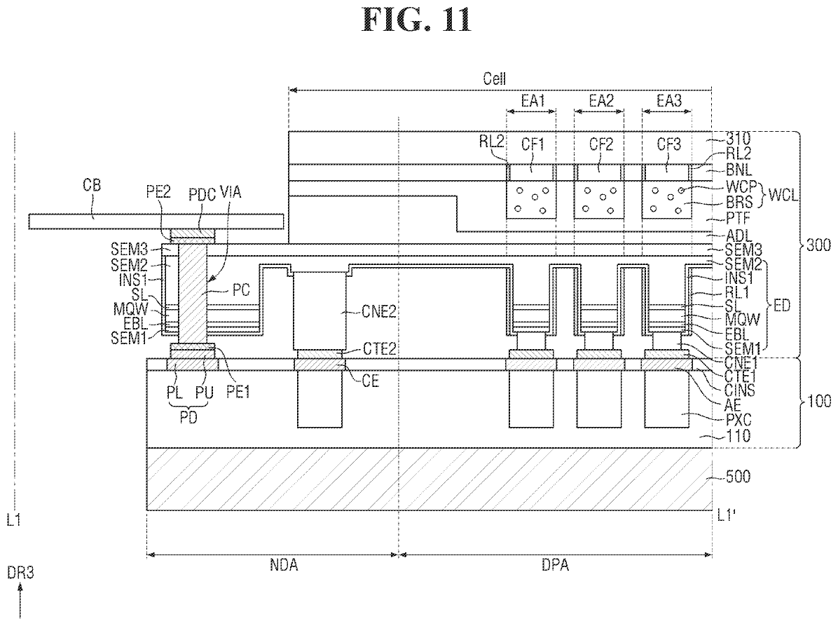

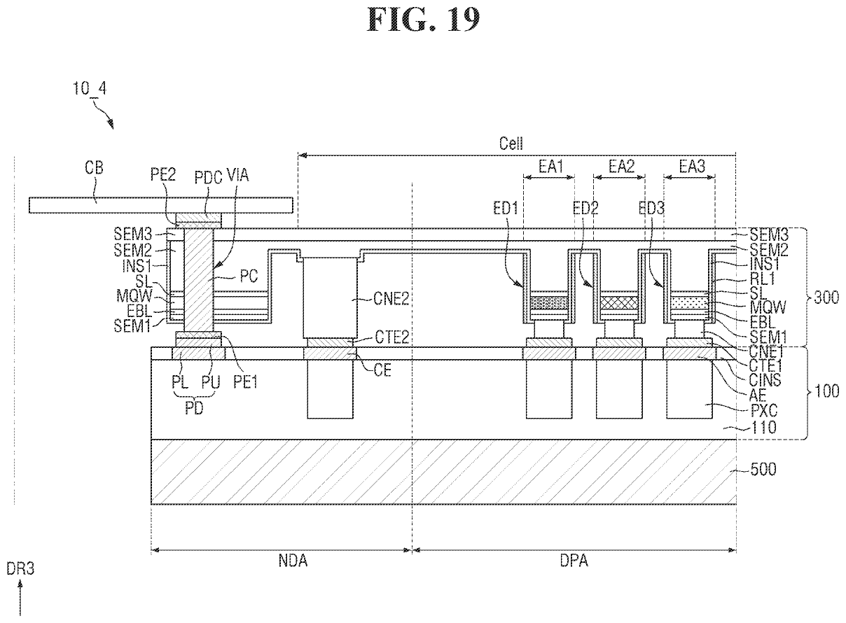

FIG. 2 is an exploded perspective view of the display device of FIG. 1. FIG. 3 is a cross-sectional view taken along the line I-I′ of FIG. 1. FIG. 4 is a cross-sectional view taken along the line II-II′ of FIG. 1. FIG. 3 illustrates a cross-sectional view taken across the display device 10 in the first direction DR1, and FIG. 4 illustrates a cross-sectional view taken across a plurality of pads PD, via holes VIA (e.g., see FIGS. 11 and 19), and circuit board pads PDC of the display device 10 in the second direction DR2.

Referring to FIGS. 2 through 4 and further to FIG. 1, the display device 10 may include a circuit substrate 100, a display substrate 300, a heat dissipation substrate 500, and a circuit board CB. The circuit substrate 100, the display substrate 300, and the circuit board CB may be located on the heat dissipation substrate 500.

The circuit substrate 100 may include pixel circuit units PXC (of FIG. 11), which are electrically connected to light-emitting elements ED (of FIG. 11) in the display substrate 300, and a plurality of pads PD, which are electrically connected to the wires of the pixel circuit units PXC. The pixel circuit units PXC may be located in the middle of the circuit substrate 100, and the pads PD may be located on both sides, with respect to the first direction DR1, of the area where the pixel circuit units PXC are located. In some embodiments where the circuit substrate 100 includes the pads PD, pads PD on one side (in the first direction DR1) of the middle of the circuit substrate 100 may be spaced apart from one another in the second direction DR2. The pads PD may be located on the top surface of the circuit substrate 100 and may be electrically connected to circuit board pads PDC of the circuit board CB.

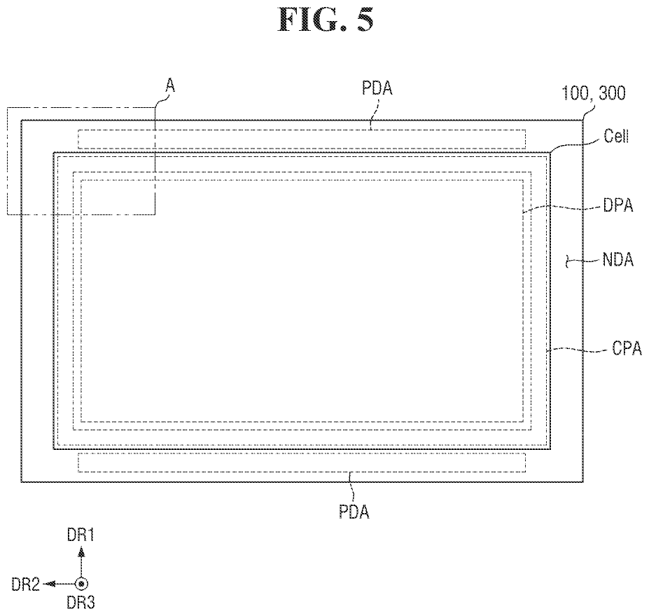

The display substrate 300 may be located on one surface of the circuit substrate 100. As will be described later, the display substrate 300 may include a display area DPA (of FIG. 5) and a non-display area NDA (of FIG. 5), and the light-emitting elements ED, which are located in the display area DPA, may receive electrical signals from the pixel circuit units PXC of the circuit substrate 100, and this may emit light. The display substrate 300 may have substantially the same size as the circuit substrate 100.

The display substrate 300 may include a cell part Cell where the light-emitting elements ED are located, and a peripheral area around the cell part Cell. The display substrate 300 of the display device 10 may include a plurality of via holes VIA, which are located adjacent to the cell part Cell and in the peripheral area. A plurality of pad connecting electrodes (PE1, PE2, and PC) may be located in the via holes VIA, and may be connected to the pads PD of the circuit substrate 100 and the circuit board pads PDC of the circuit board CB. The circuit substrate 100 and a plurality of pixels PX included in the display substrate 300 will be described later.

The heat dissipation substrate 500 may be located on the bottom surface of the circuit substrate 100, which is opposite to a surface (e.g., the top surface) of the circuit substrate 100 that faces the display substrate 300. At least part of the heat dissipation substrate 500 may overlap with the display substrate 300 in a thickness direction, and another part of the heat dissipation substrate 500 may overlap part of the circuit substrate 100 where the display substrate 300 is not located. The heat dissipation substrate 500 may include a material with a high thermal conductivity, and thus may be able to effectively release heat generated by the circuit substrate 100 and the circuit board CB. For example, the heat dissipation substrate 500 may be formed of a metallic material with a high thermal conductivity such as tungsten (W), aluminum (Al), or copper (Cu).

The circuit board CB may be located on the circuit substrate 100. The circuit board CB may include a first opening OPN1, which is formed to correspond to the cell part Cell, and the cell part Cell of the display substrate 300 may be located in the first opening OPN1 of the circuit board CB. The circuit board CB may be located in the peripheral area not to overlap with the cell part Cell in the thickness direction. The cell part Cell of the display substrate 300 may protrude from the top surface of the circuit board CB. The top surface of the cell part Cell may be higher than the top surface of the circuit board CB. The circuit board CB may be formed to have a larger area than then circuit substrate 100. The circuit board CB may have the same width as the circuit substrate 100 in the second direction DR2, and may have a greater length than the circuit substrate 100 in the first direction DR1. The circuit board CB may be located on one side, in the first direction DR1, of the display device 10 to protrude from the circuit substrate 100 (e.g., in a plan view).

The circuit board CB may be a printed circuit board (PCB), a flexible printed circuit board (FPCB), a flexible printed circuit (FPC), or a flexible film such as a chip-on-film (COF).

The circuit board CB may include the circuit board pads PDC. The circuit board pads PDC may be located on the bottom surface of a base substrate of the circuit board CB, which faces the display substrate 300, and may be connected to the pad connecting electrodes (PE1, PE2, and PC) of the display substrate 300. In some embodiments, a driving unit, which may be electrically connected to the pixel circuit units PXC of the circuit substrate 100, may be located on the circuit board CB, and the driving unit may be electrically connected to the pixel circuit units PXC through the circuit board pads PDC, the pad connecting electrodes (PE1, PE2, and PC) of the display substrate 300, and the pads PD of the circuit substrate 100.

The circuit board pads PDC of the circuit board CB may correspond to the pads PD of the circuit substrate 100 and to the pad connecting electrodes (PE1, PE2, and PC) of the display substrate 300. The circuit substrate 100 may include the pads PD, which are located on both sides (with respect to the first direction DR1), of the area where the pixel circuit units PXC are located, and the display substrate 300 may include the pad connecting electrodes (PE1, PE2, and PC), which are located on both sides of the cell part Cell (with respect to the first direction DR1). The circuit board pads PDC may correspond to the pads PD of the circuit substrate 100. The circuit board pads PDC may be located on both sides, in the first direction DR1, of the first opening OPN1. In some embodiments where the circuit board CB includes a plurality of circuit board pads PDC, circuit board pads PDC located on one side (with respect to the first direction DR1) of the first opening OPN1 may be spaced apart from one another in, or arranged along, the second direction DR2.

The number of pads PD of the circuit substrate 100 and the number of circuit board pads PDC of the circuit board CB may be the same. The pads PD may correspond one-to-one to the circuit board pads PDC, and the pads PD of the circuit substrate 100 may overlap with the circuit board pads PDC of the circuit board CB in a third direction DR3/in a plan view. However, the disclosure is not limited to this. Alternatively, each of the circuit board pads PDC may be formed to correspond to multiple pads PD. Each of the circuit board pads PDC may overlap in the third direction DR3 with, and may be electrically connected to, two or more pads PD.

The display substrate 300 of the display device 10 may include the pad connecting electrodes (PE1, PE2, and PC), which are located adjacent to the cell part Cell where the light-emitting elements ED are located, and in the peripheral area. The display device 10 may be electrically connected to the pads PD of the circuit substrate 100 and the circuit board pads PDC of the circuit board CB through the pad connecting electrodes (PE1, PE2, and PC), which are located on the display substrate 300. The circuit substrate 100 and the display substrate 300 of the display device 10 will hereinafter be described.

FIG. 5 is a plan view illustrating the circuit substrate and the display substrate of the display device of FIG. 1. FIG. 5 is a plan view illustrating the circuit substrate 100 and the display substrate 300.

Referring to FIG. 5, the display device 10 may include the display area DPA and the non-display area NDA. The display area DPA may be an area where an image is displayed, and the non-display area NDA may be an area where an image is not displayed. The display area DPA also may be referred to as an active area, and the non-display area NDA also may be referred to as an inactive area. The display area DPA may generally account for, or correspond to, the middle of each of the circuit substrate 100 and the display substrate 300. The display area DPA may be defined in common in both the circuit substrate 100 and the display substrate 300, and the non-display area NDA may be defined in the circuit substrate 100 and the display substrate 300 as an area surrounding the display area DPA. The display substrate 300 may include the light-emitting elements ED, which are located in the display area DPA, and the circuit substrate 100 may include the pixel circuit units PXC, which are located in the display area DPA and which are respectively electrically connected to the light-emitting elements ED.

The non-display area NDA may be located around the display area DPA. The non-display area NDA may surround the entire display area DPA or part of the display area DPA. The display area DPA may have a rectangular shape, and the non-display area NDA may be adjacent to the four sides of the display area DPA. The non-display area NDA may form the bezel of the display device 10. Part of the non-display area NDA may be covered by the circuit board CB.

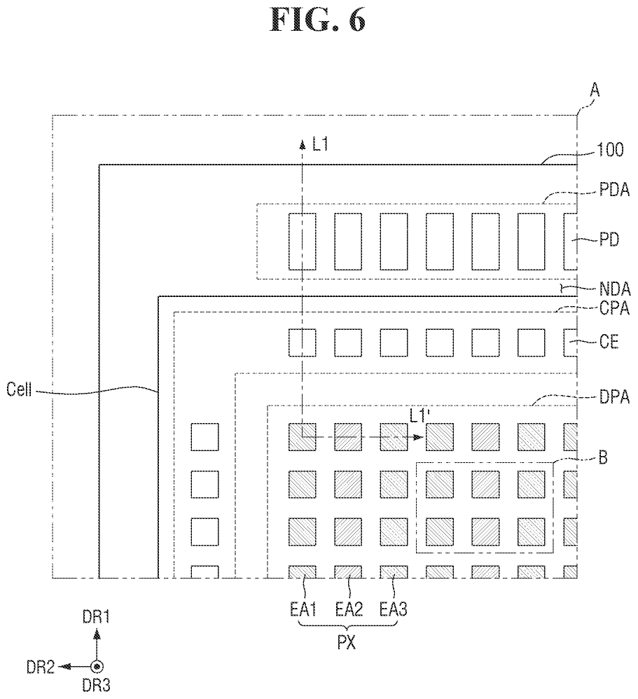

Wires or circuit driving units included in the display device 10 may be located in the non-display area NDA, and/or external devices may be mounted in the non-display area NDA. For example, the non-display area NDA may include a plurality of pad areas PDA and a common electrode connecting part CPA. The common electrode connecting part CPA may surround the display area DPA, and the pad areas PDA may extend in one direction (e.g., in the second direction DR2) from one side of the common electrode connecting part CPA. The pads PD, which are electrically connected to external devices, are located in the pad areas PDA, and common electrodes CE (of FIG. 6), which are electrically connected to the light-emitting elements ED, are located in the display area DPA. FIG. 5 illustrates that two pad areas PDA are located on either side of the display area DPA (with respect to the first direction DR1), and outside of the common electrode connecting part CPA of the non-display area NDA, but the disclosure is not limited thereto. Alternatively, less than two, or more than two, pad areas PDA may be provided. Yet alternatively, the circuit substrate 100 may further include a pad area PDA at the inside of the common electrode connecting part CPA of the non-display area NDA.

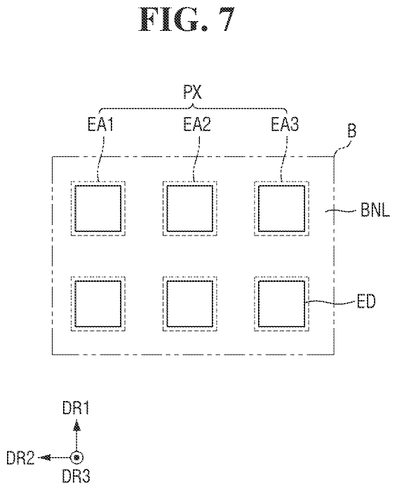

FIG. 6 is a plan view illustrating part A of FIG. 5. FIG. 7 is a plan view illustrating part B of FIG. 6. FIG. 6 is an enlarged plan view illustrating parts of the display area DPA, the pad areas PDA, and the common electrode connecting part CPA included in the circuit substrate 100 and the display substrate 300 of the display device 10, and FIG. 7 illustrates an enlarged plan view illustrating the layout of some pixels PX in the display area DPA.

Referring to FIGS. 6 and 7, the display substrate 300 of the display device 10 may include a plurality of pixels PX. The pixels PX may be arranged in row and column directions. The pixels PX may have a rectangular or square shape in a plan view, but the disclosure is not limited thereto. Alternatively, the pixels PX may have a rhombus shape having sides inclined with respect to one direction. The pixels PX may be arranged in a stripe fashion or as islands. Each of the pixels PX may include one or more light-emitting elements ED, which emit light of a corresponding wavelength range, and thus may display a corresponding color.

Each of the pixels PX may include a plurality of emission areas (EA1, EA2, and EA3), and the pixels PX may be minimal emission units of the display device 10.

For example, one pixel PX may include first, second, and third emission areas EA1, EA2, and EA3. The first emission area EA1 may emit light of a first color, the second emission area EA2 may emit light of a second color, and the third emission area EA3 may emit light of a third color. For example, the first, second, and third colors may be red, green, and blue, respectively, but the disclosure is not limited thereto. Alternatively, the first, second, and third emission areas EA1, EA2, and EA3 may emit light of the same color. For example, one pixel PX may include three emission areas (e.g., first, second, and third emission areas EA1, EA2, and EA3), but the disclosure is not limited thereto. In another example, one pixel may include four or more emission areas.

Each of the emission areas (EA1, EA2, and EA3) may include light-emitting elements ED, which emit light of a corresponding color. The light-emitting elements ED may have a rectangular shape in a plan view, but the disclosure is not limited thereto. For example, the light-emitting elements ED may have a non-tetragonal polygonal shape, a circular shape, an elliptical shape, or an amorphous shape.

The emission areas (EA1, EA2, and EA3) may be arranged in the first and second directions DR1 and DR2, and first, second, and third emission areas EA1, EA2, and EA3 may be alternately arranged in the second direction DR2. As the pixels PX are arranged in the first and second directions DR1 and DR2, the emission areas (EA1, EA2, and EA3) may be arranged repeatedly in the order of first, second, and third emission areas EA1, EA2, and EA3 in the second direction DR2. The emission areas (EA1, EA2, and EA3) also may be arranged repeatedly in the order of first, second, and third emission areas EA1, EA2, and EA3 in the first direction DR1.

The display device 10 includes a bank layer BNL, which surrounds the emission areas (EA1, EA2, and EA3), and the bank layer BNL may separate the emission areas (EA1, EA2, and EA3). The bank layer BNL may be spaced apart from the light-emitting elements ED, and may surround the light-emitting elements ED, in a plan view. The bank layer BNL may include parts extending in the first direction DR1, and parts extending in the second direction DR2, and may form a mesh, net, or lattice shape in a plan view.

FIGS. 6 and 7 illustrate that the emission areas (EA1, EA2, and EA3) surrounded by the bank layer BNL have a rectangular shape in a plan view, but the disclosure is not limited thereto. The shape of the emission areas (EA1, EA2, and EA3) may vary depending on the layout of the bank layer BNL.

A plurality of common electrodes CE may be located in the common electrode connecting part CPA of the non-display area NDA. The common electrodes CE may be spaced apart from one another, and may collectively surround the display area DPA. The common electrodes CE may be electrically connected to the light-emitting elements ED in the display area DPA. The common electrodes CE also may be electrically connected to a semiconductor circuit substrate.

FIG. 6 illustrates that the common electrode connecting part CPA is located to surround both sides of the display area DPA in the first direction DR1, and to surround both sides of the display area DPA in the second direction DR2, but the disclosure is not limited thereto. The layout of the common electrode connecting part CPA may vary depending on the layout of the common electrodes CE. For example, in a case where the common electrodes CE are arranged in one direction on one side of the display area DPA, the common electrode connecting part CPA may be formed to extend in one direction.

A plurality of pads PD may be located in each of the pad areas PDA of the circuit substrate 100. The pads PD may be electrically connected to the circuit board pads PDC, which are located on the circuit board CB. The pads PD may be spaced apart from one another in the second direction DR2 in each of the pad areas PDA. The layout of the pads PD may be designed in accordance with the number of light-emitting elements ED in the display area DPA and in accordance with the layout of wires electrically connected to the light-emitting elements ED. The layout of the pads PD may vary depending on the layout of the light-emitting elements ED and depending on the layout of the wires electrically connected to the light-emitting elements ED.

The display area DPA and the common electrode connecting part CPA may be located in the cell part Cell. In some embodiments, the display substrate 300 may include the non-display area NDA around the display area DPA, and the pad areas PDA may be located on both sides of the cell part Cell with respect to the first direction DR1. The pad connecting electrodes (PE1, PE2, and PC) may be located in the pad areas PDA of the display substrate 300. The pad connecting electrodes (PE1, PE2, and PC) may be located in the pad areas PDA to be spaced apart from one another in the second direction DR2. The layout of the pad connecting electrodes (PE1, PE2, and PC) may be designed in accordance with the layout of the pads PD of the circuit substrate 100 and the circuit board pads PDC of the circuit board CB.

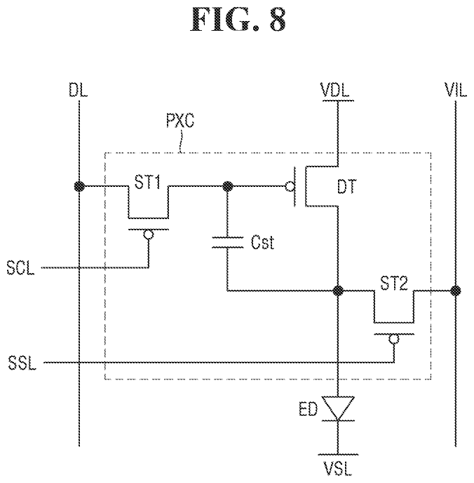

FIG. 8 is a circuit diagram illustrating a pixel circuit unit and a light-emitting element according to some embodiments of the disclosure. FIG. 8 illustrates an pixel circuit unit and an light-emitting element included in one of the pixels PX of FIG. 6.

Referring to FIG. 8, a light-emitting element ED emits light in accordance with a driving current Ids. The amount of light emitted by the light-emitting element ED may be proportional to the driving current Ids. The light-emitting element ED may be an inorganic light-emitting element including an anode, a cathode, and an inorganic semiconductor located between the anode and the cathode.

The anode of the light-emitting element ED may be connected to the source electrode of a driving transistor DT, and the cathode of the light-emitting element ED may be connected to a second power supply line VSL, to which a low-potential voltage is supplied.

The driving transistor DT controls a current flowing from a first power supply line VDL, to which a first power supply voltage is supplied, into the light-emitting element ED in accordance with the difference in voltage between the gate electrode and the source electrode of the driving transistor DT. The gate electrode of the driving transistor DT may be connected to the first electrode of a first transistor ST1, the source electrode of the driving transistor DT may be connected to the anode of the light-emitting element ED, and the drain electrode of the driving transistor DT may be connected to the first power supply line VDL, to which a high-potential voltage is applied.

The first transistor ST1 may be turned on by a scan signal from a scan line SCL, and may connect a data line DL to the gate electrode of the driving transistor DT. The gate electrode of the first transistor ST1 may be connected to the scan line SCL, the first electrode of the first transistor ST1 may be connected to the gate electrode of the driving transistor DT, and the second electrode of the first transistor ST1 may be connected to the data line DL.

A second transistor ST2 may be turned on by a sensing signal from a sensing signal line SSL to connect an initialization voltage line VIL to the source electrode of the driving transistor DT. The gate electrode of the second transistor ST2 may be connected to the sensing signal line SSL, the first electrode of the second transistor ST2 may be connected to the initialization voltage line VIL, and the second electrode of the second transistor ST2 may be connected to the source electrode of the driving transistor DT.

The first electrodes of the first and second transistors ST1 and ST2 may be, but are not limited to, source electrodes, and the second electrodes of the first and second transistors ST1 and ST2 may be, but are not limited to, drain electrodes. Alternatively, the first electrodes of the first and second transistors ST1 and ST2 may be drain electrodes, and the second electrodes of the first and second transistors ST1 and ST2 may be source electrodes.

A capacitor Cst is formed between the gate electrode and the source electrode of the driving transistor DT. The capacitor Cst may store a differential voltage corresponding to the difference between the gate voltage and the source voltage of the driving transistor DT.

FIG. 8 illustrates that the driving transistor DT and the first and second transistors ST1 and ST2 are N-type metal-oxide semiconductor field-effect transistors (MOSFETs), but the disclosure is not limited thereto. Alternatively, the driving transistor DT and the first and second transistors ST1 and ST2 may be formed as P-type MOSFETs.

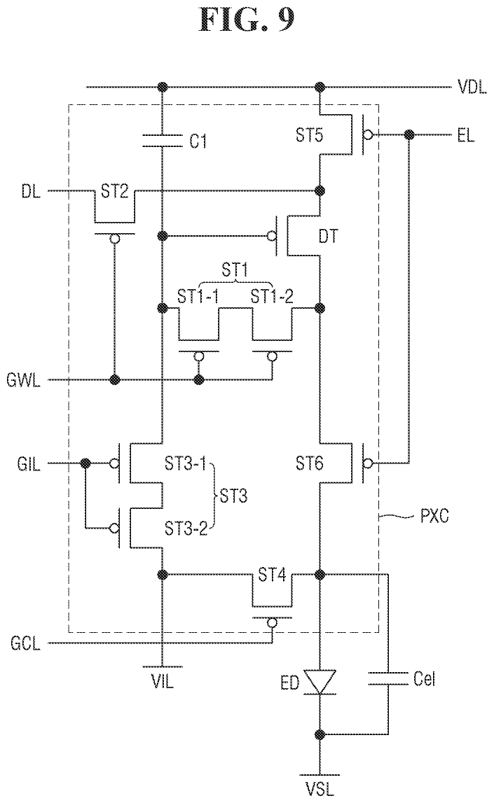

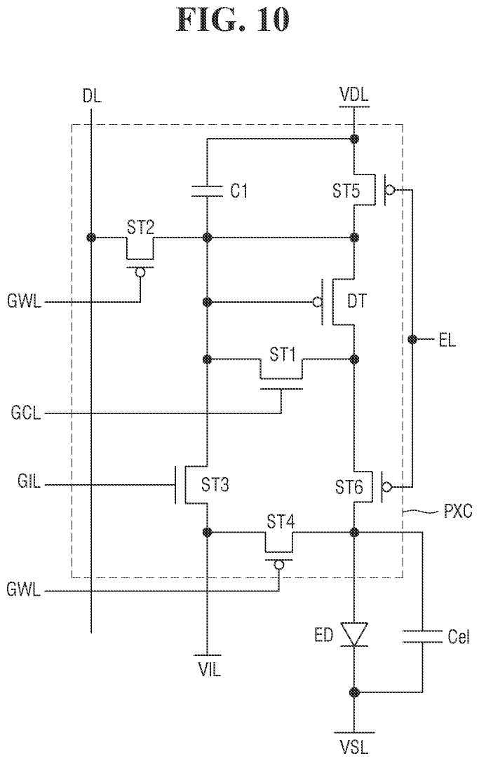

FIGS. 9 and 10 are circuit diagrams illustrating pixel circuit units and light-emitting elements according to other embodiments of the disclosure. FIGS. 9 and 10 illustrate other pixel circuit units PXC and other light-emitting elements ED. The embodiments corresponding to FIG. 10 differ from the embodiments corresponding to FIG. 9 in that a driving transistor DT, a second transistor ST2, a fourth transistor ST4, a fifth transistor ST5, and a sixth transistor ST6 are formed as P-type MOSFETs, and first and third transistors ST1 and ST3 are formed as N-type MOSFETs.

Referring to FIG. 9, the anode of a light-emitting element ED may be connected to the first electrode of a fourth transistor ST4 and to the second electrode of a sixth transistor ST6, and the cathode of the light-emitting element ED may be connected to a second power supply line VSL. A parasitic capacitor/capacitance Cel may be formed between the anode and the cathode of the light-emitting element ED.

A pixel circuit unit PXC includes a driving transistor DT, switching elements, and a capacitor C1. The switching elements include a first transistor ST1, a second transistor ST2, a third transistor ST3, the fourth transistor ST4, a fifth transistor ST5, and the sixth transistor ST6. The first transistor ST1 may include transistors ST1-1 and ST1-2 and the third transistor may include ST3-1 and ST3-2.

The driving transistor DT includes a gate electrode, a first electrode, and a second electrode. The driving transistor DT controls a driving current Ids, which is a drain-source current flowing between the first and second electrodes of the driving transistor DT, in accordance with a data voltage applied to the gate electrode of the driving transistor DT.

The capacitor C1 is formed between the gate electrode of the driving transistor DT and a first power supply line VDL. The first electrode of the capacitor C1 may be connected to the gate electrode of the driving transistor DT, and the second electrode of the capacitor C1 may be connected to the first power supply line VDL.

In a case where the first electrodes of the first, second, third, fourth, fifth, and sixth transistors ST1, ST2, ST3, ST4, ST5, and ST6 and the driving transistor DT are source electrodes, the second electrodes of the first, second, third, fourth, fifth, and sixth transistors ST1, ST2, ST3, ST4, ST5, and ST6 and the driving transistor DT may be drain electrodes. Alternatively, in a case where the first electrodes of the first, second, third, fourth, fifth, and sixth transistors ST1, ST2, ST3, ST4, ST5, and ST6 and the driving transistor DT are drain electrodes, the second electrodes of the first, second, third, fourth, fifth, and sixth transistors ST1, ST2, ST3, ST4, ST5, and ST6 and the driving transistor DT may be source electrodes.

The active layers of the first, second, third, fourth, fifth, and sixth transistors ST1, ST2, ST3, ST4, ST5, and ST6 and the driving transistor DT may be formed of any one of polysilicon, amorphous silicon, and an oxide semiconductor. For example, the active layers of the first, second, third, fourth, fifth, and sixth transistors ST1, ST2, ST3, ST4, ST5, and ST6 and the driving transistor DT may be formed of polysilicon by a low-temperature polysilicon (LTPS) process.

The first, second, third, fourth, fifth, and sixth transistors ST1, ST2, ST3, ST4, ST5, and ST6 and the driving transistor DT are illustrated in FIG. 9 as being P-type MOSFETs, but the disclosure is not limited thereto. Alternatively, the first, second, third, fourth, fifth, and sixth transistors ST1, ST2, ST3, ST4, ST5, and ST6 and the driving transistor DT may be formed as N-type MOSFETs.

A first power supply voltage from the first power supply line VDL, a second power supply voltage from the second power supply line VSL, and a third power supply voltage from an initialization voltage line VIL may be set in consideration of the characteristics of the driving transistor DT and the characteristics of the light-emitting element ED.

Referring to FIG. 10, the active layers of a driving transistor DT and second, fourth, fifth, and sixth transistors ST2, ST4, ST5, and ST6, which are formed as P-type MOSFETs, may be formed of polysilicon, and the active layers of first and third transistors ST1 and ST3, which are formed as N-type MOSFETs, may be formed of an oxide semiconductor.

The embodiments corresponding to FIG. 10 differ from the embodiments corresponding to FIG. 9 in that the gate electrodes of the second and fourth transistors ST2 and ST4 are connected to a write scan line GWL, and the gate electrode of the first transistor ST1 is connected to a control scan line GCL. In the embodiments corresponding to FIG. 10, as the first and third transistors ST1 and ST3 are formed as N-type MOSFETs, a scan signal having a gate high voltage may be applied to the control scan line GCL and an initialization scan line GIL. On the contrary, as the second, fourth, fifth, and sixth transistors ST2, ST4, ST5, and ST6 are formed as P-type MOSFETs, a scan signal having a gate low voltage may be applied to the write scan line GWL and an emission line EL.

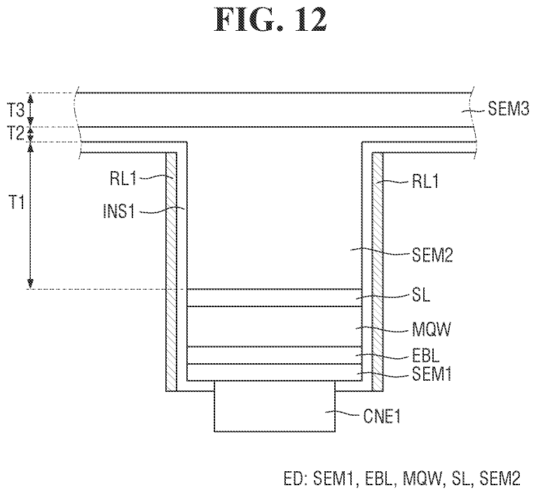

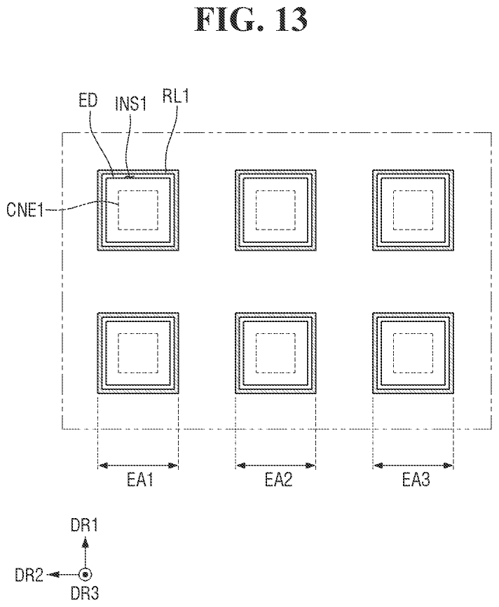

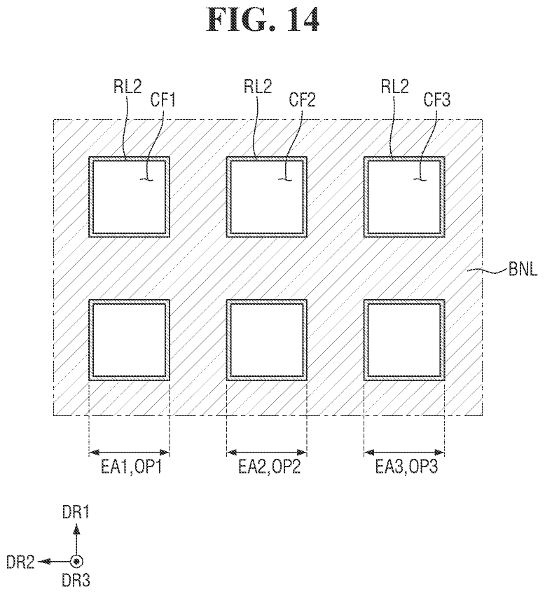

FIG. 11 is a cross-sectional view taken along the line L1-L1′ of FIG. 6. FIG. 12 is a cross-sectional view of a light-emitting element according to some embodiments of the disclosure. FIG. 13 is a plan view illustrating the layout of light-emitting elements of the display device of FIG. 1. FIG. 14 is a plan view illustrating the layout of color filters of the display device of FIG. 1. FIG. 11 illustrates a cross-sectional view taken across a pad area PDA, a common electrode connecting part, and a pixel PX in a display area DPA.

Referring to FIGS. 11 through 14, and further to FIGS. 6 and 7, a display device 10 may include a circuit substrate 100, a display substrate 300, a circuit board CB, and a heat dissipation substrate 500.

The circuit substrate 100 includes a first substrate 110 and a plurality of pixel circuit units PXC, a plurality of electrodes (AE and CE), a plurality of pads PD, and electrode connectors (CTE1 and CTE2), which are located on or in the first substrate 110. The display substrate 300 may include a plurality of light-emitting elements ED and color control structures WCL, color filters (CF1, CF2, and CF3), and a second substrate 310, which are located on the light-emitting elements ED. The pad connecting electrodes (PE1, PE2, and PC), which are located in the via holes VIA of the display substrate 300, may be located on the pads PD of the circuit substrate 100, and the circuit board pads PDC of the circuit board CB may be located on the pad connecting electrodes (PE1, PE2, and PC) of the display substrate 300.

The first substrate 110 of the circuit substrate 100 may be a semiconductor circuit substrate. The first substrate 110 may be a silicon wafer substrate formed by a semiconductor process, and may include the pixel circuit units PXC. The pixel circuit units PXC may be formed on a silicon wafer by a process of forming semiconductor circuits. Each of the pixel circuit units PXC may include at least one transistor and at least one capacitor that are formed by a semiconductor process. For example, the pixel circuit units PXC may include complementary metal-oxide semiconductor (CMOS) circuits.

The pixel circuit units PXC may be located in the display area DPA and the non-display area NDA. Pixel circuit units PXC located in the display area DPA may be electrically connected to pixel electrodes AE. The pixel circuit units PXC located in the display area DPA may respectively correspond to the pixel electrodes AE, and may respectively overlap with the light-emitting elements ED in the display area DPA (e.g., in the third direction DR3, which is the thickness direction).

Pixel circuit units PXC located in the non-display area NDA may be electrically connected to the common electrodes CE. The pixel circuit units PXC located in the non-display area NDA may correspond to the common electrodes CE, and may overlap with the common electrodes CE and with second connecting electrodes CNE2 in the non-display area NDA (e.g., in the third direction DR3).

A circuit insulating layer CINS may be located on, or at a layer that is above, the pixel circuit units PXC. The circuit insulating layer CINS may protect the pixel circuit units PXC, and may planarize height differences formed by the pixel circuit units PXC. The circuit insulating layer CINS may expose parts of the pixel electrodes AE so that the pixel electrodes AE may be electrically connected to first connecting electrodes CNE1. The circuit insulating layer CINS may include an inorganic insulating material such as silicon oxide (SiOₓ), silicon nitride (SiNₓ), silicon oxynitride (SiOₓN_{y}), aluminum oxide (AlOₓ), or aluminum nitride (AINx).

The pixel electrodes AE may be located in the display area DPA, and on their respective pixel circuit units PXC. The pixel electrodes AE may be integrally formed with the pixel circuit units PXC, and may be electrodes exposed from the pixel circuit units PXC. The common electrodes CE may be located in the common electrode connecting part CPA of the non-display area NDA, and on their respective pixel circuit units PXC. The common electrodes CE may be integrally formed with the pixel circuit units PXC, and may be electrodes exposed from the pixel circuit units PXC. The pixel electrodes AE and the common electrodes CE may include a metallic material such as Al.

The electrode connectors (CTE1 and CTE2) may be located on the pixel electrodes AE or the common electrodes CE. First electrode connectors CTE1 may be located in the display area DPA, and on their respective pixel electrodes AE. The first electrode connectors CTE1 may correspond to different pixel electrodes AE. Second electrode connectors CTE2 may be located in the common electrode connecting part CPA of the non-display area NDA, and on their respective common electrodes CE, to surround the display area DPA.

For example, the electrode connectors (CTE1 and CTE2) may be located directly on the pixel electrodes AE or the common electrodes CE, and thus may be in contact with the pixel electrodes AE or the common electrodes CE. The electrode connectors (CTE1 and CTE2) may be electrically connected to the pixel electrodes AE or the common electrodes CE and to the light-emitting elements ED. Also, the second electrode connectors CTE2 may be electrically connected to the pads PD via the pixel circuit units PXC, which are formed in the non-display area NDA.

The electrode connectors (CTE1 and CTE2) may include such a material that they are electrically connected to the pixel electrodes AE or the common electrodes CE and to the light-emitting elements ED. For example, the electrode connectors (CTE1 and CTE2) may include at least one of gold (Au), Cu, Al, and tin (Sn). Alternatively, each of the electrode connectors (CTE1 and CTE2) may include a first layer of one of Au, Cu, Al, and Sn and a second layer of another one of Au, Cu, Al, and Sn.

The pads PD may be located in the pad areas PDA of the non-display area NDA. The pads PD may be spaced apart from the common electrodes CE and the second electrode connectors CTE2. The pads PD may be spaced apart from the common electrodes CE in a direction away from the non-display area NDA.

Each of the pads PD may include a pad base layer PL and a pad upper layer PU. The pad base layer PL may be located on the first substrate 110, and the circuit insulating layer CINS may expose the pad base layer PL. The pad upper layer PU may be located directly on the pad base layer PL.

The display substrate 300 may be located on one surface of the circuit substrate 100. The display substrate 300 may include the cell part Cell where the light-emitting elements ED and the color control structures WCL are located, and also may include the peripheral area. The cell part Cell may include the display area DPA and may correspond to part of the display substrate 300 that emits light, and the pad connecting electrodes (PE1, PE2, and PC) may be located in the peripheral area.

The light-emitting elements ED of the display substrate 300 may respectively correspond to the first electrode connectors CTE1 of the circuit substrate 100. The light-emitting elements ED may be located in the display area DPA to respectively correspond to the emission areas (EA1, EA2, and EA3). One light-emitting element ED may correspond to one first, second, or third emission area EA1, EA2, or EA3.

The light-emitting elements ED may be located on the first electrode connectors CTE1 in the display area DPA. The light-emitting elements ED may be inorganic LEDs extending in one direction. The light-emitting elements ED may have a cylindrical shape having a width that is greater than its height, a disk shape, or a rod shape, but the disclosure is not limited thereto. Alternatively, the light-emitting elements ED having a wire or tube shape, a polygonal prism shape such as a cube shape, a rectangular parallelepiped shape, or a hexagonal prism shape, or an inclined shape extending in one direction and having a partially inclined outer surface. For example, the length of the light-emitting elements ED in the third direction DR3 may be greater than the width, or the length, in the horizontal direction, of the light-emitting elements ED, and may range from about 1 μm to about 5 μm.

Each of the light-emitting elements ED may include a first connecting electrode CNE1, a first semiconductor layer SEM1, an electron blocking layer EBL, an active layer MQW, a superlattice layer SL, and a second semiconductor layer SEM2. The first connecting electrode CNE1, the first semiconductor layer SEM1, the electron blocking layer EBL, the active layer MQW, the superlattice layer SL, and the second semiconductor layer SEM2 may be sequentially stacked in the third direction DR3.

First connecting electrodes CNE1 may be located on the first electrode connectors CTE1. The first connecting electrode CNE1 may be in direct contact with the first electrode connectors CTE1, and may transmit emission signals applied to the pixel electrodes AE to the light-emitting elements ED. The first connecting electrodes CNE1 may be ohmic connecting electrodes, but the disclosure is not limited thereto. Alternatively, the first connecting electrodes CNE1 may be Schottky connecting electrodes. Each of the light-emitting elements ED may include at least one first connecting electrode CNE1.

The first connecting electrodes CNE1 may reduce the contact resistance between the first electrode connectors CTE1 and the second electrode connectors CTE2 when the light-emitting elements ED are electrically connected to the electrode connectors (CTE1 and CTE2). The first connecting electrodes CNE1 may include a conductive metal. For example, the first connecting electrodes CNE1 may include at least one of Au, Cu, Sn, titanium (Ti), Al, and silver (Ag). For example, the first connecting electrodes CNE1 may include a 9:1 alloy of Au and Sn, an 8:2 alloy of Au and Sn, a 7:3 alloy of Au and Sn, or an alloy of Cu, Ag, and Sn (e.g., SAC305).

The first semiconductor layer SEM1 may be located on the first connecting electrode CNE1. The first semiconductor layer SEM1 may be p-type semiconductors, and may include a semiconductor material (e.g., AlₓGa_{y}In_{1-x-y}N (0≤x≤1, 0≤y≤1, and 0≤x+y≤1)). For example, the semiconductor material may be one of AlGaInN, GaN, AIGaN, InGaN, AIN, and InN that are doped with a p-type dopant. The first semiconductor layer SEM1 may be doped with a p-type dopant, and the p-type dopant may be magnesium (Mg), zinc (Zn), calcium (Ca), selenium (Se), or barium (Ba). For example, the first semiconductor layer SEM1 may be p-GaN doped with Mg, which is a p-type dopant.

The electron blocking layer EBL may be located on the first semiconductor layer SEM1. The electron blocking layer EBL may reduce or prevent electrons introduced into the active layer MQW and failing to recombine with holes in the active layer MQW, and then being introduced into other layers. For example, the electron blocking layer EBL may be p-AlGaN doped with Mg, which is a p-type dopant. The electron blocking layer EBL may have a thickness of about 10 nm to about 50 nm, but the disclosure is not limited thereto. In some embodiments, the electron blocking layer EBL may not be provided.

The active layer MQW may be located on the electron blocking layer EBL. As electrons and holes recombine in the active layer MQW in accordance with an emission signal applied through the first and second semiconductor layers SEM1 and SEM2, the active layer MQW may emit light. For example, the active layer MQW may emit third-color light having a central wavelength range of about 450 nm to about 495 nm (e.g., blue light).

The active layer MQW may include a material having a single- or multi-quantum well structure. In a case where the active layer MQW includes a material having a multi-quantum well structure, the active layer MQW may have a structure in which a plurality of well layers and a plurality of barrier layers are alternately stacked. Here, the well layers may be formed of, but are not limited to, InGaN, and the barrier layers may be formed of, but are not limited to, GaN or AIGaN.

For example, the active layer MQW may have a structure in which semiconductor materials having a large bandgap energy and semiconductor materials having a small bandgap energy are alternately stacked, or may include a group III semiconductor material or a group V semiconductor material depending on the wavelength range of light to be emitted by the active layer MQW. Light emitted by the active layer MQW is not particularly limited to third-color light, and in some embodiments, the active layer MQW may emit first-color light (e.g., red light) or second-color light (e.g., green light).

The superlattice layer SL may be located on the active layer MQW. The superlattice layer SL may alleviate the stress between the second semiconductor layer SEM2 and the active layer MQW. For example, the superlattice layer SL may be formed of InGaN or GaN. The superlattice layer SL may have a thickness of about 50 nm to about 200 nm. The superlattice layer SL may not be provided.

The second semiconductor layer SEM2 may be located on the superlattice layer SL. The second semiconductor layer SEM2 may be an n-type semiconductor. The second semiconductor layer SEM2 may include a semiconductor material (e.g., AlₓGa_{y}In_{1-x-y}N (0≤x≤1, 0≤y≤1, and 0≤x+y≤1)). For example, the semiconductor material may be one of AlGaInN, GaN, AIGaN, InGaN, AIN, and InN that are doped with an n-type dopant. The second semiconductor layer SEM2 may be doped with an n-type dopant, and the n-type dopant may be silicon (Si), germanium (Ge), or Sn. For example, the second semiconductor layer SEM2 may be n-GaN doped with Si, which is an n-type dopant. The second semiconductor layer SEM2 may have a thickness of about 2 μm to about 4 μm, but the disclosure is not limited thereto.

Parts of the second semiconductor layers SEM2 from different light-emitting elements ED may be connected to one another. The light-emitting elements ED may share, in common, a single second semiconductor layer SEM2 together, and layers on the second semiconductor layer SEM2 may be isolated from one another. The second semiconductor layer SEM2 may include a base layer, which extends in the first and second directions DR1 and DR2, and a plurality of protrusions, which protrude from the base layer and are spaced apart from one another. The first connecting electrodes CNE1, the first semiconductor layer SEM1, the electron blocking layer EBL, the active layers MQW, and the superlattice layer SL may be located on the protrusions of the second semiconductor layer SEM2, and may be formed as separate patterns and may form the light-emitting elements ED together with the protrusions of the second semiconductor layer SEM2. A thickness T1 of the protrusions that form parts of the light-emitting elements ED may be greater than a thickness T2 of the base layer that does not overlap with the first semiconductor layer SEM1.

The second semiconductor layer SEM2 may transmit emission signals, which are applied through the second connecting electrodes CNE2 and the second electrode connectors CTE2, to the light-emitting elements ED. As will be described later, the second connecting electrodes CNE2 may be located on one surface of the base layer of the second semiconductor layer SEM2 in the non-display area NDA, and may be electrically connected to the common electrodes CE through the second electrode connectors CTE2.

A third semiconductor layer SEM3 may be located on the second semiconductor layer SEM2. The third semiconductor layer SEM3 may be located in the display area DPA and part of the non-display area NDA, and may be located on the entire surface of the base layer of the second semiconductor layer SEM2. The third semiconductor layer SEM3 may be an undoped semiconductor. The third semiconductor layer SEM3 may include the same material as the second semiconductor layer SEM2, for example, a material not doped with an n- or p-type dopant. The third semiconductor layer SEM3 may be at least one of InAIGaN, GaN, AIGaN, InGaN, AIN, and InN that are not doped, but the disclosure is not limited thereto.

The third semiconductor layer SEM3, unlike the second semiconductor layer SEM2, may not have conductivity, and emission signals applied to the pixel electrodes AE and the common electrodes CE may flow through the light-emitting elements ED and the second semiconductor layer SEM2. During the fabrication of the light-emitting elements ED, the second semiconductor layer SEM2 and the light-emitting elements ED may be formed on the third semiconductor layer SEM3. A thickness T3 of the third semiconductor layer SEM3 may be less than the thickness T1 of the protrusions of the second semiconductor layer SEM2, and may be greater than the thickness T2 of the base layer of the second semiconductor layer SEM2.

The second connecting electrodes CNE2 may be located in the common electrode connecting part CPA of the non-display area NDA. The second connecting electrodes CNE2 may be located on one surface of the base layer of the second semiconductor layer SEM2. The second connecting electrodes CNE2 may be located directly on the second electrode connectors CTE2, and may transmit emission signals, which are applied from the common electrodes CE, to the light-emitting elements ED. The second connecting electrodes CNE2 may be formed of the same material as the first connecting electrodes CNE1. The second connecting electrodes CNE2 may be thicker than the first connecting electrodes CNE1 in the third direction DR3.

A first insulating layer INS1 may be located on one surface of the base layer of the second semiconductor layer SEM2 and on side surfaces of each of the light-emitting elements ED. The first insulating layer INS1 may surround at least the light-emitting elements ED (e.g., in a plan view). Parts of the first insulating layer INS1 that surround the light-emitting elements ED may correspond to the light-emitting elements ED, and thus may be spaced apart from one another in the first and second directions DR1 and DR2, in a plan view. The first insulating layer INS1 may protect the light-emitting elements ED, and may insulate the second semiconductor layer SEM2 and the light-emitting elements ED from other layers. The first insulating layer INS1 may include an inorganic insulating material such as SiOₓ, SiNₓ, SiOₓN_{y}, AlOₓ, or AlNₓ.

First reflective layers RL1 may surround the side surfaces of each of the light-emitting elements ED. The first reflective layers RL1 may be located directly on parts of the first insulating layer INS1 on the side surfaces of each of the light-emitting elements ED to correspond to the emission areas (EA1, EA2, and EA3) in the display area DPA. The first reflective layers RL1 may correspond to, and surround, the light-emitting elements ED, which are spaced apart from one another, and the first reflective layers RL1 may be spaced apart from one another in the first and second directions DR1 and DR2 in a plan view. The first reflective layers RL1 may reflect light emitted from the active layer MQW, and the reflected light may travel toward the second substrate 310, rather than toward the first substrate 110.

The first reflective layers RL1 may include a metallic material with high reflectance, such as Al. The first reflective layers RL1 may have a thickness of about 0.1 μm, but the disclosure is not limited thereto.

The first semiconductor layer SEM1, the electron blocking layer EBL, the active layer MQW, the superlattice layer SL, the second semiconductor layer SEM2, and the third semiconductor layer SEM3 also may be formed in the peripheral area near the cell part Cell of the display substrate 300. The light-emitting elements ED of the display substrate 300 may be obtained by sequentially forming the second semiconductor layer SEM2, the superlattice layer SL, the active layer MQW, the electron blocking layer EBL, and the first semiconductor layer SEM1 on the third semiconductor layer SEM3, and dividing each of the second semiconductor layer SEM2, the superlattice layer SL, the active layer MQW, the electron blocking layer EBL, and the first semiconductor layer SEM1 into sections corresponding to the emission areas (EA1, EA2, and EA3). The third semiconductor layer SEM3 may be located in an entirety of the cell part Cell and in an entirety of the peripheral area near the cell part Cell, and the first semiconductor layer SEM1, the electron blocking layer EBL, the active layer MQW, the superlattice layer SL, and the second semiconductor layer SEM2 also may remain in the peripheral area near the cell part Cell. Pad areas PDA, which are similar to their respective counterparts of the circuit substrate 100, may be located in the peripheral area, and a plurality of via holes VIA may be located in the pad areas PDA of the peripheral area. The via holes VIA may penetrate at least parts of the first semiconductor layer SEM1, the electron blocking layer EBL, the active layer MQW, the superlattice layer SL, the second semiconductor layer SEM2, and the third semiconductor layer SEM3, as will be described later.

The cell part Cell of the display substrate 300 may include a passivation layer PTF, the color control structures WCL, the color filters (CF1, CF2, and CF3), second reflective layers RL2, a bank layer BNL, and the second substrate 310.

The second substrate 310 may face the first substrate 110. The second substrate 310 may be a base substrate supporting a plurality of layers included in the display substrate 300. The second substrate 310 may be formed of a transparent material. For example, the second substrate 310 may include a transparent substrate such as a sapphire (Al₂O₃) substrate or a glass substrate, but the disclosure is not limited thereto. In another example, the second substrate 310 may be a conductive substrate formed of GaN, SiC, ZnO, Si, GaP, or GaAs.

The bank layer BNL may be located on one surface of the second substrate 310. The bank layer BNL may surround the first emission areas EA1, the second emission areas EA2, and the third emission areas EA3. The bank layer BNL may include parts extending in the first direction DR1 and parts extending in the second direction DR2, and thus may form a lattice shape in the entire display area DPA. The bank layer BNL also may be located in the non-display area NDA to completely cover the surface of the second substrate 310.

The bank layer BNL may include, or define, a plurality of opening holes (OP1, OP2, and OP3), which expose the second substrate 310, in the display area DPA. The opening holes (OP1, OP2, and OP3) may include first opening holes OP1, which overlap with the first emission areas EA1, second opening holes OP2, which overlap with the second emission areas EA2, and third opening holes OP3, which overlap with the third emission areas EA3. The opening holes (OP1, OP2, and OP3) may correspond to the emission areas (EA1, EA2, and EA3).

The bank layer BNL may include Si. For example, the bank layer BNL may include a silicon single-crystal layer. The bank layer BNL may be formed by reactive ion etching (RIE). The bank layer BNL may be formed to have a high aspect ratio by controlling a set of etching conditions.

The color filters (CF1, CF2, and CF3) may be located on the surface of the second substrate 310, in the opening holes (OP1, OP2, and OP3) of the bank layer BNL. The color filters (CF1, CF2, and CF3) may be spaced apart from one another with the bank layer BNL located therebetween, but the disclosure is not limited thereto.

The color filters (CF1, CF2, and CF3) may include first color filters CF1, second color filters CF2, and third color filters CF3. The first color filters CF1 may be located in the first opening holes OP1 of the bank layer BNL to overlap with the first emission areas EA1. The second color filters CF2 may be located in the second opening holes OP2 of the bank layer BNL to overlap with the second emission areas EA2, and the third color filters CF3 may be located in the third opening holes OP3 of the bank layer BNL to overlap with the third emission areas EA3.

The color filters (CF1, CF2, and CF3) may fill the opening holes (OP1, OP2, and OP3), and surfaces of the color filters (CF1, CF2, and CF3) may be on a level with a surface of the bank layer BNL. That is, the thickness of the color filters (CF1, CF2, and CF3) may be the same as the thickness of the bank layer BNL, but the disclosure is not limited thereto. Alternatively, the surfaces of the color filters (CF1, CF2, and CF3) may protrude from, or may be recessed from, the surface of the bank layer BNL. That is, the thickness of the color filters (CF1, CF2, and CF3) may differ from the thickness of the bank layer BNL.

The color filers (CF1, CF2, and CF3) may be located as island patterns to correspond to the openings (OP1, OP2, and OP3) of the bank layer BNL, but the disclosure is not limited thereto. Alternatively, the color filters (CF1, CF2, and CF3) may be formed as linear patterns extending in one direction in the display area DPA. In this case, the opening holes (OP1, OP2, and OP3) of the bank layer BNL also may be formed to extend in one direction. The first color filters CF1 may be red filters, the second color filters CF2 may be green filters, and the third color filters CF3 may be blue filters. The color filters (CF1, CF2, and CF3) may transmit therethrough some of light that is emitted from the light-emitting elements ED and that is transmitted through the color control structures WCL, and may block the transmission of the other light.

The second reflective layers RL2 may be located in the opening holes (OP1, OP2, and OP3) of the bank layer BNL. The second reflective layers RL2 may be located on side surfaces of the bank layer BNL, and may surround side surfaces of each of the color filters (CF1, CF2, and CF3), which are located in the opening holes (OP1, OP2, and OP3). The second reflective layers RL2 may be located in different opening holes (OP1, OP2, and OP3) to surround different color filters (CF1, CF2, and CF3) and may be spaced apart from one another in the first and second directions DR1 and DR2 in a plan view.

The second reflective layers RL2, like the first reflective layers RL1, may reflect light incident thereupon. Some of light emitted from the light-emitting elements ED and incident upon the color filters (CF1, CF2, and CF3) may be reflected by the second reflective layers RL2, and then may be emitted toward the top surface of the second substrate 310. The second reflective layers RL2 may include the same material as the first reflective layers RL1. For example, the second reflective layers RL2 may include a metallic material with high reflectance such as Al. The second reflective layers RL2 may have a thickness of about 0.1 μm, but the disclosure is not limited thereto.

The color control structures WCL may be located on (e.g., below) the color filters (CF1, CF2, and CF3). The color control structures WCL may overlap with the first color filters CF1, the second color filters CF2, and the third color filters CF3, and may be spaced apart from one another. The color control structures WCL may correspond to the opening holes (OP1, OP2, and OP3) of the bank layer BNL, and may overlap with the opening holes (OP1, OP2, and OP3). The color control structures WCL may be formed as island patterns that are spaced apart from one another, but the disclosure is not limited thereto. Alternatively, the color control structures WCL may be formed as linear patterns extending in one direction.

The color control structures WCL may convert or shift the peak wavelength of incident light into a suitable peak wavelength. In some embodiments where the light-emitting elements ED emit third-color light (e.g., blue light), the color control structures WCL may convert at least some of the light emitted from the light-emitting elements ED into fourth-color light (e.g., yellow light). The third-color light emitted by the light-emitting elements ED may be converted into fourth-color light (e.g., yellow light) by the color control structures WCL, and mixed light (e.g., the mixture of the third-color light and the fourth-color light) may be incident upon the color filters (CF1, CF2, and CF3). The first color filters CF1 may transmit therethrough first-color light (e.g., red light) among the mixed light, and may block the other mixed light. Similarly, the second color filters CF2 may transmit therethrough second-color light (e.g., green light) among the mixed light, and may block the other mixed light, while the third color filters CF3 may transmit therethrough third-color light (e.g., blue light) among the mixed light, and may block the other mixed light.

Each of the color control structures WCL may include a base resin BRS and wavelength-converting particles WCP. The base resin BRS may include a transparent organic material. For example, the base resin BRS may be formed of an epoxy resin, an acrylic resin, a cardo resin, or an imide resin. The base resins BRS of the color control structures WCL may be all formed of the same material, but the disclosure is not limited thereto. The wavelength-converting particles WCP may be a material converting third-color light (e.g., blue light) into fourth-color light (e.g., yellow light). The wavelength-converting particles WCP may be quantum dots, quantum rods, or phosphors. The quantum dots may include group IV nanocrystals, group II-VI compound nanocrystals, group III-V compound nanocrystals, group IV-VI nanocrystals, or a combination thereof.

Each of the color control structures WCL may further include a scatterer. The scatterer may be particles of a metal oxide or an organic material. Here, the metal oxide may be titanium oxide (TiO₂), zirconium oxide (ZrO₂), aluminum oxide (Al₂O₃), indium oxide (In₂O₃), zinc oxide (ZnO), or tin oxide (SnO₂), and the organic material may be an acrylic resin or a urethane resin.

As the thickness (in the third direction DR3) of the color control structures WCL increases, the content of the wavelength-converting particles WCP in the color control structures WCL increases, and as a result, the light conversion efficiency of the color control structures WCL may increase. The thickness of the color control structures WCL may be designed in consideration of the light conversion efficiency of the wavelength-converting particles WCP.

The passivation layer PTF may be located on (e.g., below) the bank layer BNL and the color control structures WCL, and may cover (e.g., overlap) the bank layer BNL and the color control structures WCL. The passivation layer PTF may be located in the entire display area DPA and the at least portion of non-display area NDA. The passivation layer PTF may protect the color control structures WCL in the display area DPA, and may planarize height differences formed by the color control structures WCL.

The passivation layer PTF may be located between the light-emitting elements ED and the color control structures WCL, and may prevent the wavelength conversion particles WCP of each of the color control structures WCL from being damaged by heat from the light-emitting elements ED. The passivation layer PTF may include an organic insulating material, such as an epoxy resin, an acrylic resin, a cardo resin, or an imide resin.

An adhesive layer ADL may be located between the third semiconductor layer SEM3 and the passivation layer PTF of the display substrate 300. The adhesive layer ADL may bond the third semiconductor layer SEM3 and the passivation layer PTF together, and may be formed of a transparent material to transmit light emitted from the light-emitting elements ED therethrough. For example, the adhesive layer ADL may include an acrylic material, a silicon-based material, or a urethane-based material, and may include a material that can be ultraviolet (UV)-cured or thermally cured.

The circuit board CB may be located on the display substrate 300. As the circuit board CB includes the first opening OPN1, which corresponds to the cell part Cell of the display substrate 300, the circuit board CB may overlap with the peripheral area. The circuit board CB may include the base substrate and the circuit board pads PDC, which are located on the bottom surface of the base substrate, and the circuit board pads PDC may be electrically connected to the pads PD of the circuit substrate 100. The pads PD of the circuit substrate 100, and the circuit board pads PDC of the circuit board CB, may be electrically connected via the pad connecting electrodes (PE1, PE2, and PC) of the display substrate 300.

The pads PD of the circuit substrate 100 may be located in the pad areas PDA, and the circuit board pads PDC of the circuit board CB may correspond to the pads PD. The display substrate 300 may include the via holes VIA, which are located in the pad areas PDA of the peripheral area, and the pad connecting electrodes (PE1, PE2, and PC), which are located in the via holes VIA.

The via holes VIA may penetrate the display substrate 300 from the top surface to the bottom surface of the display substrate 300 in the peripheral area. The via holes VIA may be formed to correspond to the pads PD of the circuit substrate 100. In some embodiments where the pad areas PDA are located on both sides of the display area DPA (in the first direction DR1), the via holes VIA may be located on both sides of the cell part Cell of the display substrate 300 (in the first direction DR1). Via holes VIA located on one side of the cell part Cell (with respect to the first direction DR1), like their respective pads PD, may be arranged in the second direction DR2.

The via holes VIA may penetrate at least some of the first semiconductor layer SEM1, the electron blocking layer EBL, the active layer MQW, the superlattice layer SL, the second semiconductor layer SEM2, and the third semiconductor layer SEM3 in the peripheral area of the display substrate 300. For example, the via holes VIA penetrate the first semiconductor layer SEM1, the electron blocking layer EBL, the active layer MQW, the superlattice layer SL, the second semiconductor layer SEM2, and the third semiconductor layer SEM3 from the bottom surface of the first semiconductor layer SEM1 to the top surface of the third semiconductor layer SEM3. The via holes VIA may overlap with the pads PD of the circuit substrate 100 and the circuit board pads PDC of the circuit board CB in the thickness direction. The pads PD and the circuit board pads PDC may overlap at least parts of the first semiconductor layer SEM1, the electron blocking layer EBL, the active layer MQW, the superlattice layer SL, the second semiconductor layer SEM2, and the third semiconductor layer SEM3 that are located in the peripheral area of the display substrate 300.

The pad connecting electrodes (PE1, PE2, and PC) may be located in the via holes VIA. The pad connecting electrodes (PE1, PE2, and PC) may include a conductive material, and may be electrically connected to the pads PD and the circuit board pads PDC. The pad connecting electrodes (PE1, PE2, and PC) may include connecting parts PC, which are located in the via holes VIA, first electrode parts PE1, which are connected to the connectors PC and are located on the bottom surface of the display substrate 300, and second electrode parts PE2, which are connected to the connecting parts PC and are located on the top surface of the display substrate 300. In some embodiments where the via holes VIA penetrate the first semiconductor layer SEM1, the electron blocking layer EBL, the active layer MQW, the superlattice layer SL, the second semiconductor layer SEM2, and the third semiconductor layer SEM3 in the peripheral area, the first electrode parts PE1 may be located on (e.g., may contact) the bottom surface of the first semiconductor layer SEM1, and the second electrode parts PE2 may be located on the top surface of the third semiconductor layer SEM3.

The first electrode parts PE1 may be electrically connected to the pads PD of the circuit substrate 100, and the second electrode parts PE2 may be electrically connected to the circuit board pads PDC of the circuit board CB. The first electrode parts PE1 may be bonded to the pads PD of the circuit substrate 100 via an anisotropic conductive film (ACF) or via soldering, heat, or laser light. Similarly, the second electrode parts PE2 may be bonded to the circuit board pads PDC of the circuit board CB.

The via holes VIA and the pad connecting electrodes (PE1, PE2, and PC) of the display substrate 300 may provide paths via which the pads PD of the circuit substrate 100 below the display substrate 300, and the circuit board pads PDC of the circuit board CB above the display substrate 300, are electrically connected. The pads PD, the circuit board pads PDC, the via holes VIA, and the pad connecting electrodes (PE1, PE2, and PC) may correspond to one another, and the numbers of pads PD, circuit board pads PDC, via holes VIA, and pad connecting electrodes (PE1, PE2, and PC) may all be the same. Also, the pads PD, the circuit board pads PDC, the via holes VIA, and the pad connecting electrodes (PE1, PE2, and PC) may all have substantially the same layout in a plan view.

The display device 10 may be fabricated by arranging the display substrate 300 on the circuit substrate 100, and by arranging the circuit board CB on the display substrate 300. As the circuit board CB is located above the circuit substrate 100 such that the circuit board pads PDC and the pads PD can be electrically connected by the pad connecting electrodes (PE1, PE2, and PC), the structure and the fabrication of the display device 10 can be simplified. For example, a process of exposing the pads PD of the circuit substrate 100 after the arrangement of the display substrate 300 on the circuit substrate 100 can be omitted. Also, as the circuit board CB is not located on the bottom surface of the circuit substrate 100, the bottom surface of the circuit substrate 100 can be formed to be substantially flat. The display device 10 may have a suitable structure for effectively releasing heat generated by the circuit substrate 100 and the display substrate 300.

Display devices according to other embodiments of the disclosure will hereinafter be described.

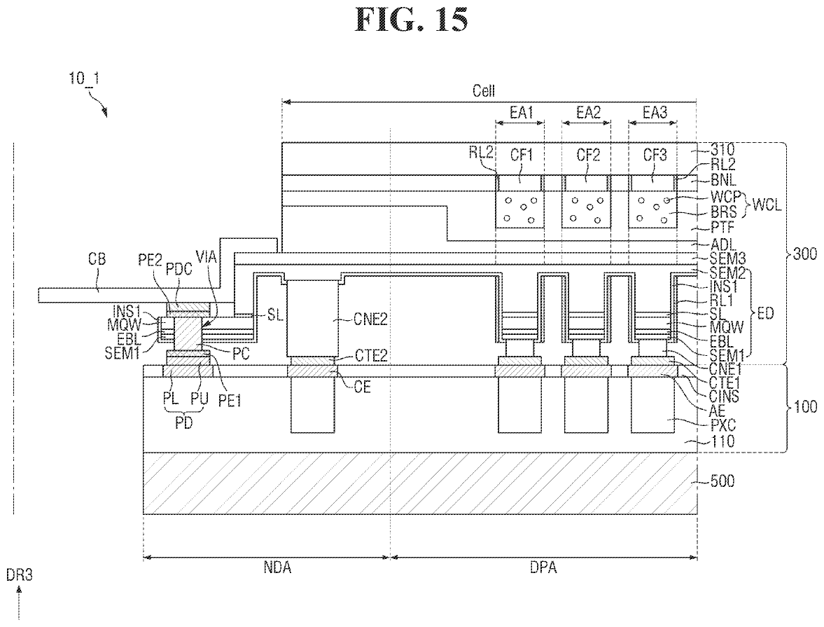

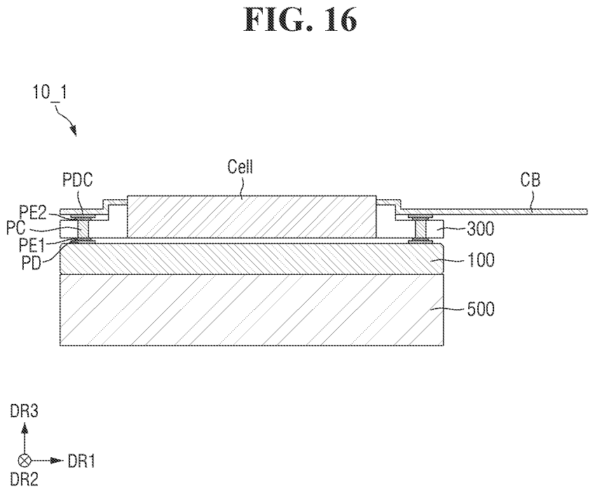

FIG. 15 is a cross-sectional view illustrating part of a display device according to other embodiments of the disclosure. FIG. 16 is a cross-sectional view taken across the display device of FIG. 15 in the second direction DR2.

Referring to a display device 10_1 of FIGS. 15 and 16, parts of second and third semiconductor layers SEM2 and SEM3 may be removed from a peripheral area around a cell part Cell, and via holes VIA may penetrate an active layer MQW and layers below the active layer MQW. The third semiconductor layer SEM3, the second semiconductor layer SEM2, and a superlattice layer SL may be partially removed from the peripheral area, and the top surface of the active layer MQW may be exposed. As the third semiconductor layer SEM3, the second semiconductor layer SEM2, and the superlattice layer SL are partially removed, the top surface of the active layer MQW may be exposed in the via holes VIA, and the via holes VIA may penetrate only the active layer MQW, the electron blocking layer EBL, and the first semiconductor layer SEM1. Second electrode parts PE2 may be located on the active layer MQW.

A circuit board CB may include a first opening OPN1, which corresponds to the cell part Cell of a display substrate 300, and may overlap with the peripheral area of the display substrate 300. As a base substrate of the circuit board CB is located in the peripheral area, and is located not only in regions where the third semiconductor layer SEM3, the second semiconductor layer SEM2, and the superlattice layer SL are not removed, but is also located in regions where the via holes VIA are formed, the base substrate of the circuit board CB may be located along height differences in the peripheral area. As color control structures WCL are located in the cell part Cell, the cell part Cell may have a greatest thickness, and the peripheral area may have a lesser thickness than the cell part Cell. As parts of the second and third semiconductor layers SEM2 and SEM3 are removed from the peripheral area, parts of the peripheral area may be thinner than the rest of the peripheral area, and a plurality of via holes VIA and pad connecting electrodes (PE1, PE2, and PC) may be located in parts of the peripheral area around the Cell having a small thickness. The top surface of parts of the peripheral area where the via holes VIA are formed may be lower than the top surface of the rest of the peripheral area. The circuit board CB may surround the cell part Cell and may be partially stepped in accordance with the height of the peripheral area.

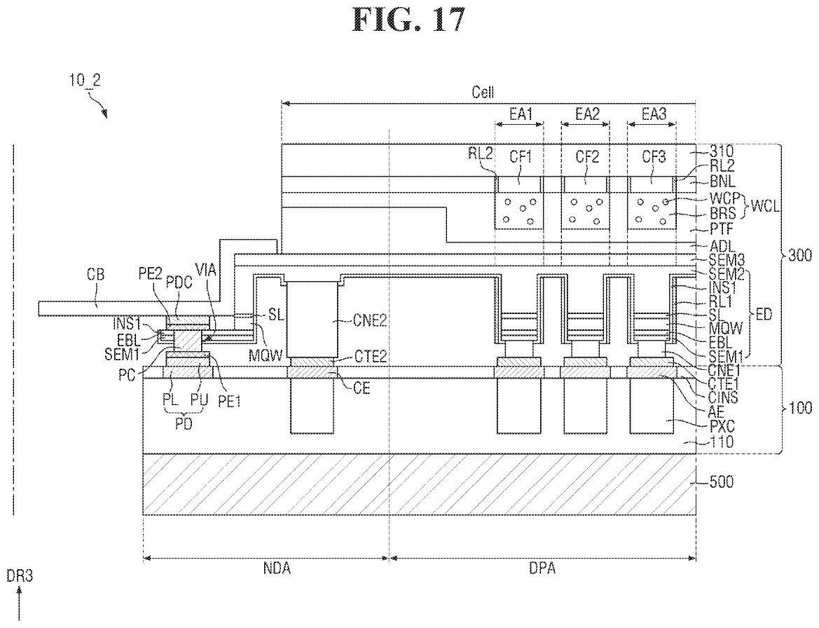

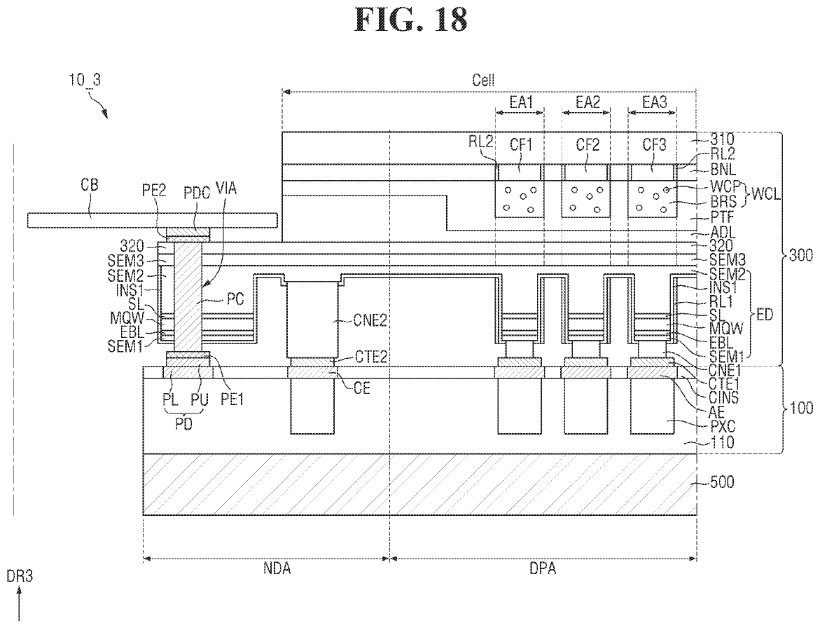

FIGS. 17 and 18 are cross-sectional views illustrating parts of display devices according to other embodiments of the disclosure.

Referring to a display device 10_2 of FIG. 17, a third semiconductor layer SEM3, a second semiconductor layer SEM2, a superlattice layer SL, and an active layer MQW may be partially removed from a peripheral area around a cell part Cell of a display substrate 300, and via holes VIA may penetrate only an electron blocking layer EBL and a first semiconductor layer SEM1. In the peripheral area, the third semiconductor layer SEM3, the second semiconductor layer SEM2, the superlattice layer SL, and the active layer MQW may be partially removed, and the top surface of the electron blocking layer EBL may be exposed. The via holes VIA may penetrate only the electron blocking layer EBL and the first semiconductor layer SEM1, and second electrode parts PE2 may be located on the electron blocking layer EBL. The display device 10_2 differs from the display device 10_1 of FIGS. 15 and 16 in that not only the third semiconductor layer SEM3, the second semiconductor layer SEM2, and the superlattice layer SL, but also the active layer MQW is partially removed from the peripheral area.

The second electrode parts PE2 are illustrated as being located on the electron blocking layer EBL due to the electron blocking layer EBL not being removed, but the disclosure is not limited thereto. Alternatively, even the electron blocking layer EBL may be partially removed from the peripheral area, and the via holes VIA may penetrate only the first semiconductor layer SEM1. In this case, the second electrode parts PE2 may be located on the first semiconductor layer SEM1.

The display substrate 300 may further include another substrate located on the third semiconductor layer SEM3. Referring to a display device 10_3 of FIG. 18, a display substrate 300 may further include a third substrate 320, which is located on a third semiconductor layer SEM3, and via holes VIA, which are located in a peripheral area around a cell part Cell, may penetrate the third substrate 320, a third semiconductor layer SEM3, a second semiconductor layer SEM2, a superlattice layer SL, an active layer MQW, an electron blocking layer EBL, and a first semiconductor layer SEM1. Second electrode parts PE2 may be located on the third substrate 320.

A plurality of layers may be stacked on the third semiconductor layer SEM3, thereby forming light-emitting elements ED and the peripheral area. The third semiconductor layer SEM3 may be located on the third substrate 320, and the display substrate 300 may be located on a circuit substrate 100 together with the third substrate 320. In the previous embodiments, color control structures WCL and color filters (CF1, CF2, and CF3) may be located on the third semiconductor layer SEM3 with the third substrate 320 removed. However, in the embodiments corresponding to FIG. 18, the third substrate 320 may remain, and the color control structures WCL and the color filters (CF1, CF2, and CF3) may be located on the third substrate 320. The third substrate 320 may be located in the entire cell part Cell and in the entire peripheral area, and the via holes VIA may penetrate the third substrate 320 in the peripheral area. The third substrate 320 may be a transparent substrate, such as a sapphire substrate or a glass substrate, or may be a conductive substrate formed of GaN, SiC, ZnO, Si, GaP, or GaAs.

FIG. 19 is a cross-sectional view illustrating part of a display device according to other embodiments of the disclosure.

Referring to a display device 10_4 of FIG. 19, a display substrate 300 may include different light-emitting elements (ED1, ED2, and ED3) in different emission areas (EA1, EA2, and EA3), and may omit color control structures WCL and color filters (CF1, CF2, and CF3) on a third semiconductor layer SEM3.

Light-emitting elements (ED1, ED2, and ED3), which are located in emission areas (EA1, EA2, and EA3), may include different active layers MQW and may emit light of different colors. The light-emitting elements (ED1, ED2, and ED3) may include first light-emitting elements ED1, which are located in first emission areas EA1, second light-emitting elements ED2, which are located in second emission areas EA2, and third light-emitting elements ED3, which are located in third emission areas EA3. The light-emitting elements (ED1, ED2, and ED3) may emit light of different wavelengths depending on the material of the active layers MQW thereof. For example, the first light-emitting elements ED1 may emit first-color light (e.g., red light), the second light-emitting elements ED2 may emit second-color light (e.g., green light), and the third light-emitting elements ED3 may emit third-color light (e.g., blue light).

A circuit board CB may include a first opening OPN1 (e.g., see FIG. 2), which corresponds to a cell part Cell, and may be located not to overlap with the cell part Cell. As the circuit board CB is not located on the light-emitting elements (ED1, ED2, and ED3), light emitted from the light-emitting elements (ED1, ED2, and ED3) may be emitted in an upward direction, even though the top surface of the display substrate 300 does not protrude from the top surface of the circuit board CB.

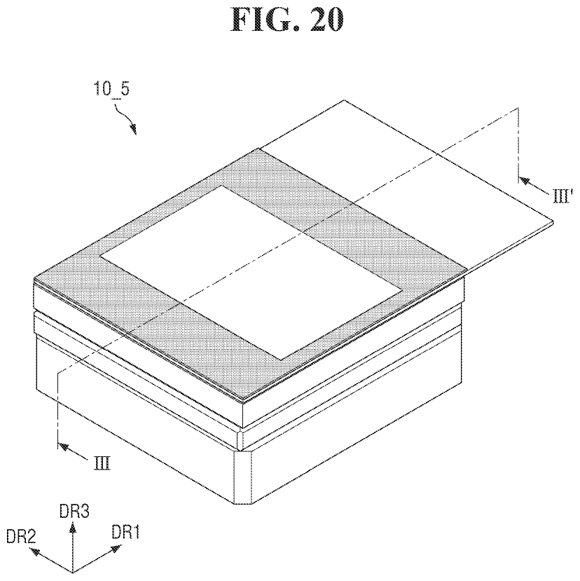

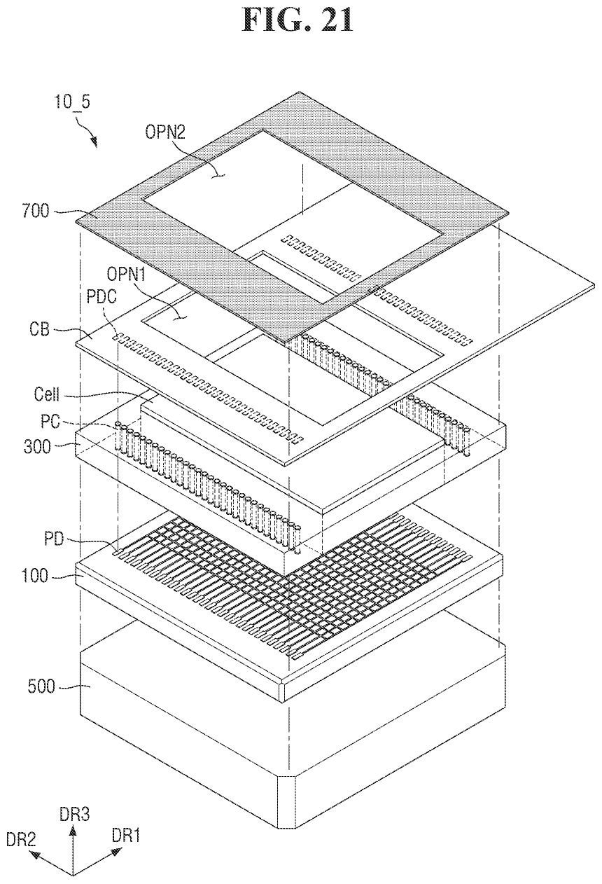

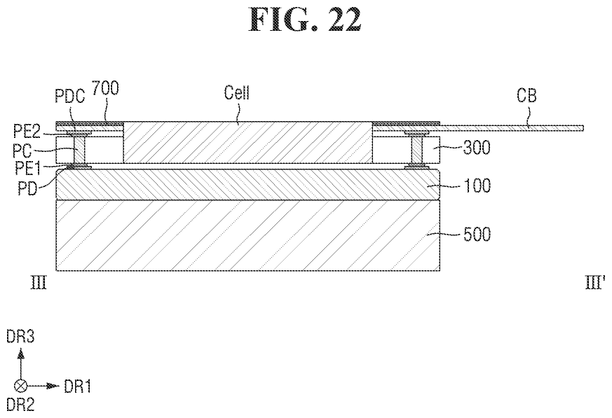

FIG. 20 is a perspective view of a display device according to other embodiments of the disclosure. FIG. 21 is an exploded perspective view of the display device of FIG. 20. FIG. 22 is a cross-sectional view taken along the line III-III′ of FIG. 20. FIG. 22 illustrates a cross-sectional view taken across a display device 10_5 of FIG. 20 in a first direction DR1.

Referring to FIGS. 20 through 22, the display device 10_5 may further include a light-blocking layer 700. The light-blocking layer 700 may have a shape corresponding to the overlapping area of a circuit board CB, a circuit substrate 100, and a display substrate 300. The light-blocking layer 700 may generally have the same shape as the circuit board CB, and may include a second opening OPN2, which corresponds to a cell part Cell of the display substrate 300. The light-blocking layer 700, like the circuit board CB, might not overlap with the cell part Cell of the display substrate 300. The length of the light-blocking layer 700 in the first direction DR1 may be less than the length of the circuit board CB in the first direction DR1, and may be substantially the same as the length of the circuit substrate 100 in the first direction DR1. The light-blocking layer 700 may overlap with circuit board pads PDC and pads PD in a thickness direction, and may overlap with the entire display substrate 300 except for the cell part Cell.

The light-blocking layer 700 may include a material capable of blocking the transmission of light. The light-blocking layer 700 may reduce or prevent light generated by the cell part Cell of the display substrate 300 from being emitted sideways (as opposed to in the upward direction), and may reduce or prevent visibility of a peripheral area around the cell part Cell from outside the display device 10_5. Alternatively, the light-blocking layer 700 may include a metallic material, and may further include the material capable of blocking the transmission of light. The light-blocking layer 700 may reduce or prevent the leakage of light emitted from the cell part Cell, and may protect the circuit substrate 100 and the display substrate 300 from static electricity.

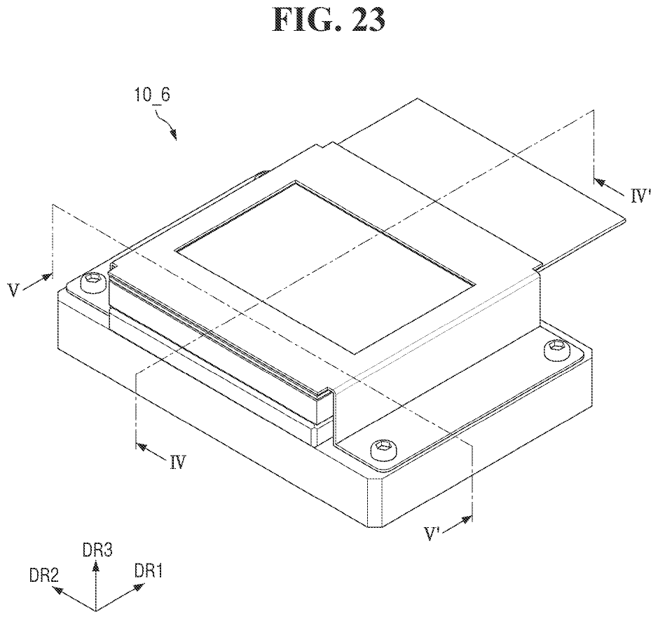

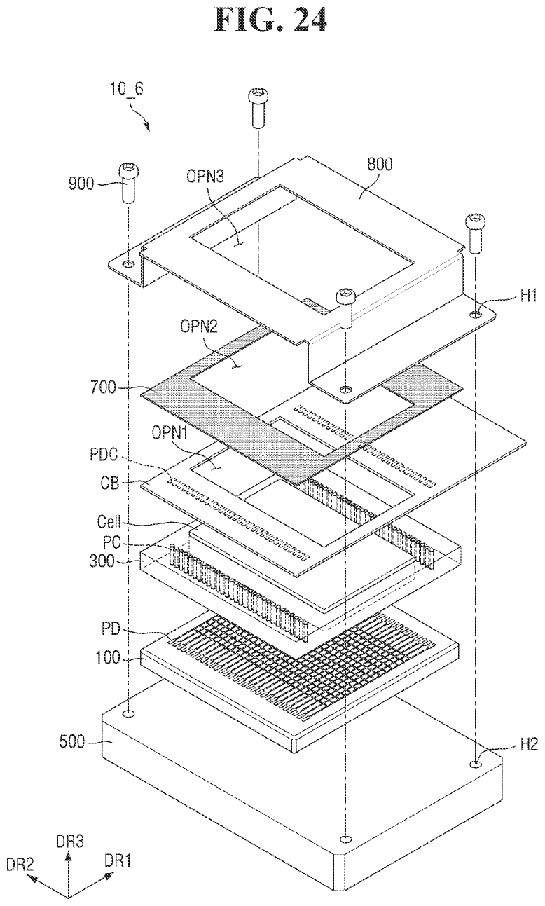

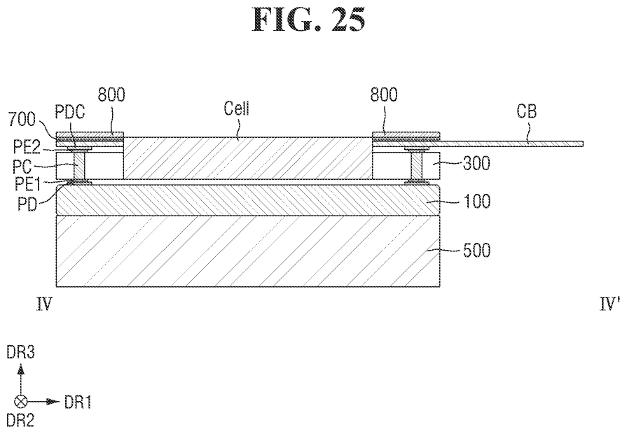

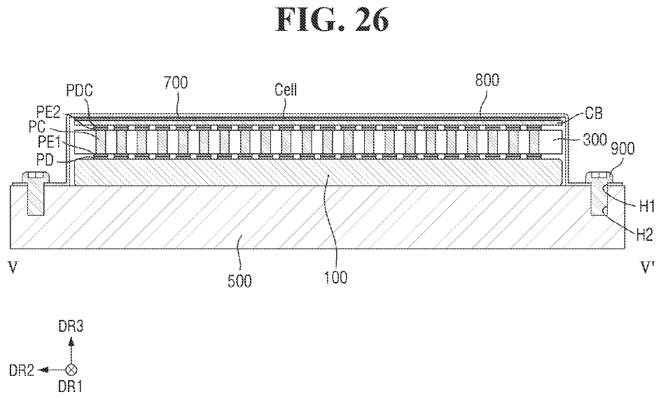

FIG. 23 is a perspective view of a display device according to other embodiments of the disclosure. FIG. 24 is an exploded perspective view of the display device of FIG. 23. FIG. 25 is a cross-sectional view taken along the line IV-IV′ of FIG. 23. FIG. 26 is a cross-sectional view taken along the line V-V′ of FIG. 23. FIG. 25 illustrates a cross-sectional view taken across a display device 10_6 of FIG. 23 in a first direction DR1, and FIG. 26 illustrates a cross-sectional view taken across the display device 10_6 in a second direction DR2.

Referring to FIGS. 23 through 26, the display device 10_6 may further include a cover substrate 800 and coupling parts 900, which are located on a circuit board CB and a light-blocking layer 700. The display device 10_6 differs from the display device 10_5 of FIG. 20 in that it further includes the cover substrate 800, which is an external substrate, and the cover substrate 800 is coupled to a heat dissipation substrate 500 via the coupling parts 900. The cover substrate 800 and the coupling parts 900 will hereinafter be described.

The cover substrate 800 may be coupled to the heat dissipation substrate 500 via the coupling parts 900, and may fix a circuit substrate 100, a display substrate 300, and the circuit board CB, which are located between the cover substrate 800 and the heat dissipation substrate 500.

The heat dissipation substrate 500 may have a larger size than the circuit substrate 100, and part of the heat dissipation substrate 500 might not overlap with the circuit substrate 100 and the display substrate 300. The coupling parts 900 may be inserted in the part of the heat dissipation substrate 500 that does not overlap with the circuit substrate 100, so that the heat dissipation substrate 500 may be coupled to the cover substrate 800.

The cover substrate 800 may have substantially the same size as the heat dissipation substrate 500 in a plan view. The cover substrate 800, like the circuit board CB, may include an opening (e.g., a third opening OPN3), which corresponds to a cell part Cell of the display substrate 300. The cover substrate 800 may overlap with the circuit substrate 100, the display substrate 300 excluding the cell part Cell, the circuit board CB, the light-blocking layer 700, and the heat dissipation substrate 500. The cover substrate 800 may overlap with pads PD of the circuit substrate 100, via holes VIA of the display substrate 300, and circuit board pads PDC of the circuit board CB, and may overlap with only the heat dissipation substrate 500 outside of, or beyond the edges of, the circuit substrate 100.

The cover substrate 800 may include a first part, which covers the circuit substrate 100 and has the third opening OPN3 formed therein, and second parts, which are connected to the first part in the second direction DR2 and in the opposite direction of the second direction DR2. The second parts of the cover substrate 800 may be formed to be bent in a downward direction, which is opposite to a third direction DR3, from the first part. As the circuit substrate 100 has a smaller size than the heat dissipation substrate 500, part of the top surface of the heat dissipation substrate 500 may be exposed due to the absence of the circuit substrate 100 thereon. The cover substrate 800 may include the second parts, which are bent along the circuit substrate 100. The first part of the cover substrate 800 may cover the circuit substrate 100, and the second parts of the cover substrate 800 may expose the exposed part of the heat dissipation substrate 500.

The cover substrate 800 may be formed of a material capable of providing a coupling force such that the cover substrate 800, which forms the exterior of the display device 10_6, can protect and completely fix the circuit substrate 100 and the circuit board CB. For example, the cover substrate 800 may be formed of a plastic material with rigidity or a metallic material.

The cover substrate 800 may include first holes H1, which are formed in the second parts, and the heat dissipation substrate 500 may include second holes H2, which are formed to correspond to, or overlap, the first holes H1. The first holes H1 may be formed to penetrate the cover substrate 800, and the second holes H2 may be formed on the top surface of the heat dissipation substrate 500, but not to penetrate the heat dissipation substrate 500, but the disclosure is not limited thereto. Alternatively, the second holes H2 may be formed to penetrate the heat dissipation substrate 500.

The display device 10_6 may include the first holes H1 and the second holes H2, and the first holes H1 may be formed to correspond to the second holes H2. In some embodiments where the display device 10_6 has a rectangular shape with four sides extending in the first and second directions DR1 and DR2, the cover substrate 800 may include four first holes H1, and the heat dissipation substrate 500 may include four second holes H2. The first holes H1 and the second holes H2 may be located on the sides of the display device 10 that extend in the first direction DR1, but the disclosure is not limited thereto. Alternatively, the display device 10 may include four or more (or less than four) first holes H1 and four or more (or less than four) second holes H2 depending on the shape of the display device 10. The cover substrate 800 may be located on the circuit board CB such that the first holes H1 may be aligned with the second holes H2 of the heat dissipation substrate 500, and the cover substrate 800 and the heat dissipation substrate 500 may be coupled together via the coupling parts 900, which are inserted in the first holes H1 and the second holes H2.

The coupling parts 900 may be inserted in the second holes H2 through the first holes H1. The coupling parts 900 may completely fix the cover substrate 800 to the heat dissipation substrate 500. The coupling parts 900 may be, for example, rivets or bolts, and may mechanically couple the cover substrate 800 and the heat dissipation substrate 500.

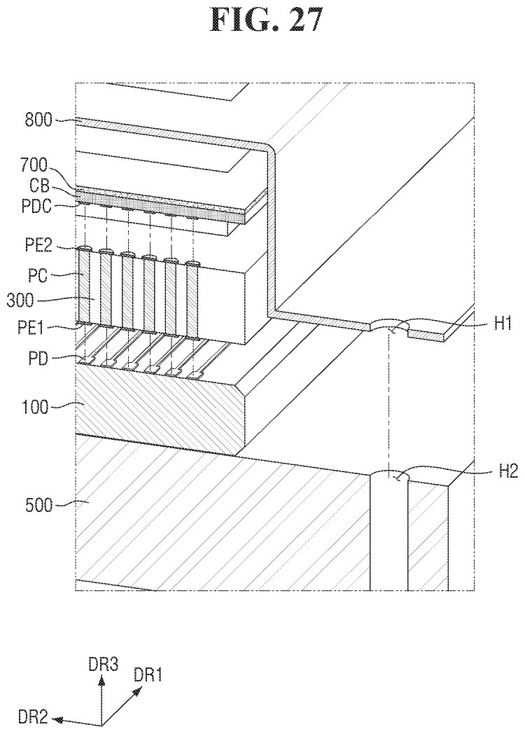

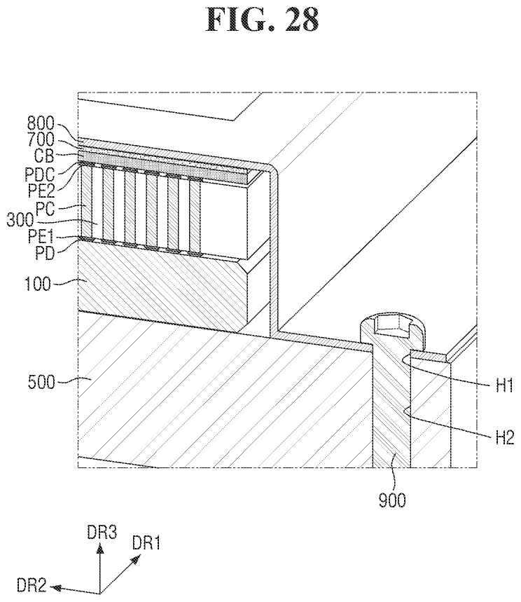

FIG. 27 is a perspective view illustrating the layers in part of the display device of FIG. 23. FIG. 28 is a perspective view illustrating part of the display device of FIG. 23. FIG. 27 illustrates the heat dissipation substrate 500, the cover substrate 800, the circuit board CB, and the circuit substrate 100 as being detached from one another at a corner of the display device 10_6, and FIG. 28 illustrates the heat dissipation substrate 500 and the cover substrate 800 as being coupled together so that the circuit board CB and the circuit substrate 100 are in contact with each other.

Referring to FIGS. 27 and 28 and further to FIGS. 23 through 26, the circuit substrate 100, the display substrate 300, and the circuit board CB, which are located between the cover substrate 800 and the heat dissipation substrate 500, may be completely fixed, or secured, by the cover substrate 800 and the heat dissipation substrate 500. The circuit substrate 100, the display substrate 300, and the circuit board CB may be aligned such that the pads PD, the via holes VIA, and the circuit board pads PDC may correspond to one another. The cover substrate 800 may be coupled to the heat dissipation substrate 500 and may fix or secure the circuit substrate 100, the display substrate 300, and the circuit board CB in a state of being in contact with one another. The first part of the cover substrate 800 may be located on a surface of the circuit board CB that is opposite to a surface of the circuit board CB where the circuit board pads PDC are formed. The first part of the cover substrate 800 may overlap with regions where the pads PD, the via holes VIA, and the circuit board pads PDC are located, and may apply a force such that the pads PD, pad connecting electrodes (PE1, PE2, and PC), and the circuit board pads PDC may be fixed in a state of being in contact with one another.

The pads PD of the circuit substrate 100, the pad connecting electrodes (PE1, PE2, and PC) of the display substrate 300, and the circuit board pads PDC of the circuit board CB may be fixed in a state of being in physical contact with one another, and the circuit board pads PDC and the pads PD may be electrically connected to one another. The pads PD, the pad connecting electrodes (PE1, PE2, and PC), and the circuit board pads PDC may be in contact with one another to form physical interfaces therebetween, rather than being bonded via other members or being fusion-bonded through the fusion of conductive materials. There may not be any signs of the pads PD, the pad connecting electrodes (PE1, PE2, and PC), and the circuit board pads PDC being fusion-bonded together. Instead, there may exist physical interfaces between the pads PD, the pad connecting electrodes (PE1, PE2, and PC), and the circuit board pads PDC, and as processes of bonding the pads PD, the pad connecting electrodes (PE1, PE2, and PC), and the circuit board pads PDC are not needed, the fabrication of the display device 10_6 can be simplified. Also, because the circuit substrate 100 and the circuit board CB can be detached by removing the coupling parts 900, the repair or the reassembly of the display device 10_6 can be facilitated in case of, for example, poor electrical connections between the pads PD and the circuit board pads PDC.

Display devices according to embodiments of the disclosure are applicable to a variety of devices or equipment as displays for displaying an image.

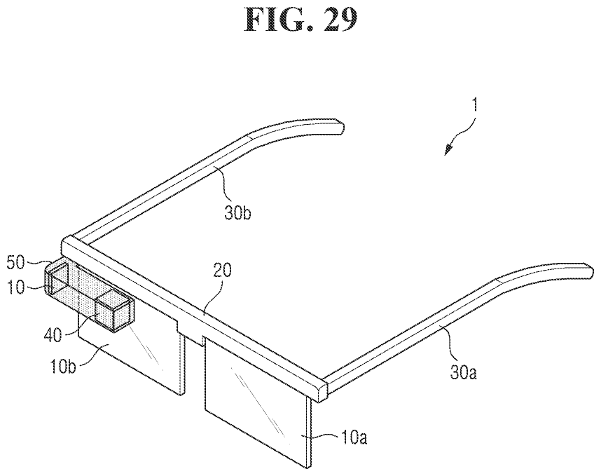

FIGS. 29 through 31 are perspective views illustrating devices each including one or more display devices according to some embodiments of the disclosure.

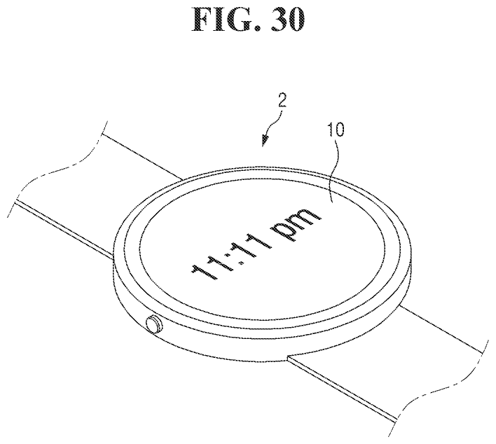

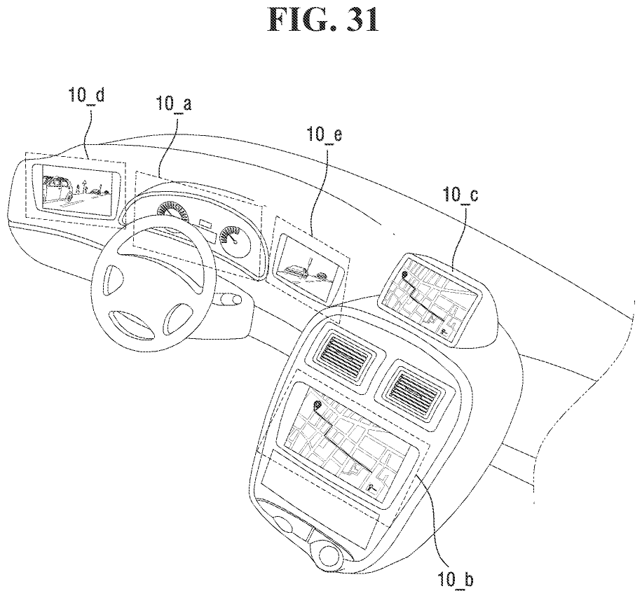

FIG. 29 illustrates a virtual reality (VR) device with a display device according to some embodiments of the disclosure applied thereto, and FIG. 30 illustrates a smartwatch with a display device according to some embodiments of the disclosure applied thereto. FIG. 31 illustrates an automobile display with display devices according to some embodiments of the disclosure applied thereto.

Referring to FIG. 29, a VR device 1 may be an eyeglass-type device. The VR device 1 may include a display device 10, a left-eye lens 10a, a right-eye lens 10b, a support frame 20, eyeglass temples 30a and 30b, a reflective member 40, and a display device storage compartment 50.

FIG. 29 illustrates the VR device 1 including the eyeglass temples 30a and 30b, but the VR device 1 also may be applicable to a head-mounted display (HMD) including a headband that can be worn on the head, instead of the eyeglass temples 30a and 30b. The VR device 1 is not particularly limited to that illustrated in FIG. 29 and may be applicable to various types of electronic devices.

The display device storage compartment 50 may include the display device 10 and the reflective member 40. An image displayed by the display device 10 may be reflected by the reflective member 40, and thus may be provided to the right eye of a user through the right-eye lens 10b. Thus, the user may view a VR image, displayed by the display device 10, through his or her right eye.

The display device storage compartment 50 may be located at the right end of the support frame 20, but the disclosure is not limited thereto. Alternatively, the display device storage compartment 50 may be located at the left end of the support frame 20, and an image displayed by the display device 10 may be reflected by the reflective member 40, and thus may be provided to the right eye of the user through the left-eye lens 10a. As a result, the user may view a VR image displayed by the display device 10 with his or her left eye. Yet alternatively, two display device storage compartments 50 may be located at both the left and right ends of the support frame 20, in which case, the user may view a VR image, displayed by the display device 10, through both his or her left and right eyes.

Referring to FIG. 30, a display device 10 may be applied to a smartwatch 2, which is a type of smart device.

Referring to FIG. 31, display devices 10_a, 10_b, and 10_c may be applied to the dashboard or center console of an automobile or to a center information display (CID) in the dashboard of an automobile. Display devices 10_d and 10_e may be applied to room mirror displays that can replace the rear view mirrors of an automobile.

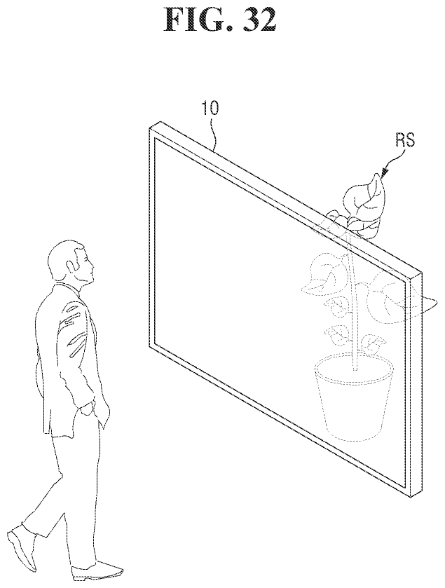

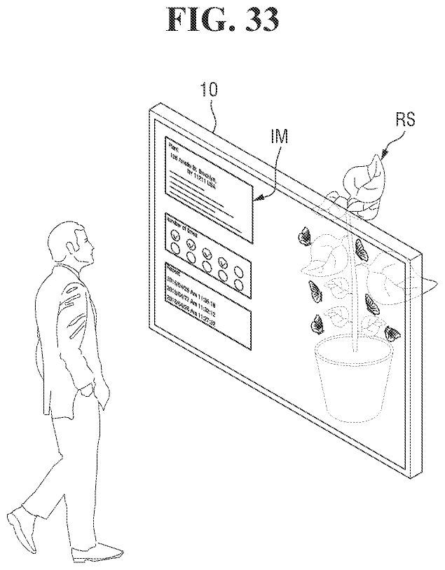

FIGS. 32 and 33 are perspective views of transparent display devices including a display device according to some embodiments of the disclosure.

Referring to FIGS. 32 and 33, a display device 10 may be applied to a transparent display device. The transparent display device may display an image IM and at the same time, transmit light therethrough. A user at the front of the transparent display device may view not only the image IM on the display device 10, but also an object RS or the background at the rear of the transparent display device. A circuit substrate 100, a display substrate 300, a heat dissipation substrate 500, and a circuit board CB of the display device 10 may include light-transmitting parts capable of transmitting light therethrough or may be formed of a material capable of transmitting light therethrough.

In concluding the detailed description, those skilled in the art will appreciate that many variations and modifications can be made to the disclosed embodiments without substantially departing from the aspects of the present disclosure. Therefore, the disclosed embodiments of the present disclosure are used in a generic and descriptive sense only and not for purposes of limitation, and it will be understood by those of ordinary skill in the art that various changes in form and details may be made therein without departing from the spirit or scope of the present disclosure corresponding to the following claims, with functional equivalents thereof to be included therein.

What is claimed is:

1. A display device comprising:
a circuit substrate comprising pixel circuit units, and pads electrically connected to the pixel circuit units;
a display substrate above the circuit substrate, comprising light-emitting elements electrically connected to the pixel circuit units, and defining via holes in a peripheral area around a cell part where the light-emitting elements are located;
a circuit board above the display substrate, and comprising circuit board pads electrically connected to the pads;
a heat dissipation substrate below the circuit substrate; and
pad connecting electrodes in the via holes, and connected to the pads of the circuit substrate and to the circuit board pads of the circuit board.

2. The display device of claim 1, wherein the pad connecting electrodes comprise first electrode parts connected to the pads, second electrode parts connected to the circuit board pads, and connecting parts in the via holes and connected to the first electrode parts and to the second electrode parts.

3. The display device of claim 2, wherein the via holes and the circuit board pads correspond to the pads, and
wherein a number of via holes and a number of the circuit board pads are the same as a number of pads.

4. The display device of claim 2, wherein the light-emitting elements comprise a first semiconductor layer, an active layer on the first semiconductor layer, and a second semiconductor layer on the active layer,
wherein the first semiconductor layer, the active layer, and the second semiconductor layer are further in the peripheral area around the cell part, and
wherein the display substrate further comprises a third semiconductor layer in both the cell part, and in the peripheral area around the cell part.

5. The display device of claim 4, wherein the pads and the circuit board pads overlap with a part of the first semiconductor layer, the active layer, or the second semiconductor layer in the peripheral area around the cell part.

6. The display device of claim 4, wherein the via holes penetrate the first semiconductor layer, the active layer, the second semiconductor layer, and the third semiconductor layer in the peripheral area around the cell part, and
wherein the second electrode parts are on the third semiconductor layer.

7. The display device of claim 4, wherein parts of the second semiconductor layer and the third semiconductor layer are omitted from the peripheral area around the cell part, and
wherein the via holes penetrate the active layer and the first semiconductor layer in the peripheral area around the cell part where the second semiconductor layer and the third semiconductor layer are omitted.

8. The display device of claim 7, wherein a top surface of the display substrate is lower in regions where the via holes are located than in other regions of the peripheral area around the cell part.

9. The display device of claim 4, wherein the display substrate further comprises color control structures on the third semiconductor layer in the cell part, color filters on the color control structures, and a second substrate on the color filters.

10. The display device of claim 9, wherein the display substrate further comprises a third substrate on the third semiconductor layer,
wherein the via holes penetrate the third substrate, and
wherein the second electrode parts are on the third substrate.

11. The display device of claim 4, wherein parts of the second semiconductor layer in the light-emitting elements are connected to part of the second semiconductor layer in the peripheral area around the cell part.

12. The display device of claim 1, wherein the circuit board defines a first opening corresponding to the cell part of the display substrate, and
wherein the circuit board does not overlap with the cell part of the display substrate, and is in the peripheral area around the cell part.

13. The display device of claim 12, wherein a top surface of the cell part of the display substrate protrudes from a top surface of the circuit board.

14. The display device of claim 12, further comprising a light-blocking layer on the circuit board, and defining a second opening corresponding to the cell part of the display substrate.

15. A display device comprising:
a circuit substrate comprising a display area, and pad areas where pads are located;
a display substrate above the circuit substrate, comprising a cell part where light-emitting elements correspond to the display area, defining via holes corresponding to the pads in a peripheral area around the cell part, and further comprising pad connecting electrodes in the via holes;
a circuit board above the display substrate, defining a first opening corresponding to the cell part of the display substrate, and comprising circuit board pads corresponding to the pads;
a light-blocking layer above the circuit board, and defining a second opening corresponding to the cell part of the display substrate; and
a heat dissipation substrate below the circuit substrate,
wherein the pad connecting electrodes comprise first electrode parts connected to the pads, second electrode parts connected to the circuit board pads, and connecting parts connected to the first electrode parts and the second electrode parts and in the via holes.

16. The display device of claim 15, wherein the light-emitting elements comprise a first semiconductor layer, an active layer on the first semiconductor layer, and a second semiconductor layer on the active layer in the peripheral area around the cell part, and
wherein the display substrate further comprises a third semiconductor layer in both the cell part, and the peripheral area around the cell part.

17. The display device of claim 16, wherein the via holes penetrate the first semiconductor layer, the active layer, the second semiconductor layer, and the third semiconductor layer in the peripheral area around the cell part, and wherein the second electrode parts are on the third semiconductor layer.

18. The display device of claim 16, wherein the display substrate further comprises color control structures on the third semiconductor layer in the cell part, color filters on the color control structures, and a second substrate on the color filters, and
wherein a top surface of the cell part of the display substrate is higher than a top surface of the circuit board.

19. The display device of claim 15, wherein the circuit board pads are at a bottom surface of the circuit board.

20. The display device of claim 15, wherein a number of the via holes and a number of the circuit board pads are the same as a number of the pads.
